(19) United States
(12) Patent Application Publication
(10) Pub. No.: US 2026/0206433 A1
(43) Pub. Date: Jul. 16, 2026

(54) DISPLAY DEVICE, ELECTRONIC DEVICE AND METHOD FOR FABRICATING DISPLAY DEVICE

(71) Applicant: Samsung Display Co., Ltd., Yongin-si (KR)

(72) Inventor: Chun Gi YOU, Yongin-si (KR)

(21) Appl. No.: 19/302,860

(22) Filed: Aug. 18, 2025

(30) Foreign Application Priority Data
Jan. 13, 2025 (KR) 10-2025-0004909

(51) Int. Cl. H10K 59/131; H10K 59/12; H10K 59/80

(52) U.S. Cl. CPC H10K 59/131; H10K 59/1201; H10K 59/878

(57) ABSTRACT

A display device includes: a substrate comprising a first sub-pixel area and a second sub-pixel area; a connection electrode in the first sub-pixel area and the second sub-pixel area on the substrate; a reflective layer on the connection electrodes; an optical auxiliary layer on the connection electrodes surrounding the reflective layer; a first electrode on the substrate and the connection electrodes surrounding the optical auxiliary layer and the connection electrodes, and contacting side surfaces of the connection electrodes; a capping layer on the first electrodes and comprising openings overlapping the first electrodes; a light emitting stack on the first electrodes and the capping layer; and a second electrode on the light emitting stack.

### CROSS-REFERENCE TO RELATED APPLICATION

The present application claims priority to and the benefit of Korean Patent Application No. 10-2025-0004909, filed on Jan. 13, 2025, in the Korean Intellectual Property Office, the entire disclosure of which is incorporated herein by reference.

### BACKGROUND

### 1. Field

Aspects of some embodiments of the present disclosure may relate to a display device.

### 2. Description of the Related Art

An organic light emitting display apparatus may include display elements whose luminance is changed by a current, such as organic light emitting diodes.

The above information disclosed in this Background section is only for enhancement of understanding of the background and therefore the information discussed in this Background section does not necessarily constitute prior art.

### SUMMARY

Aspects of some embodiments of the present disclosure may relate to a display device, and for example, to a display device, an electronic device, and a method for fabricating the display device that may be capable of preventing or reducing damage of a reflective layer during a process.

However, aspects of embodiments according to the present disclosure are not restricted to those set forth herein. The above and other aspects of embodiments according to the present disclosure will become more apparent to one of ordinary skill in the art to which embodiments according to the present disclosure pertains by referencing the detailed description of the present disclosure given below.

According to some embodiments of the present disclosure, a display device includes: a substrate including first and second sub-pixel areas; connection electrodes in the first and second sub-pixel areas on the substrate; reflective layers on the connection electrodes; optical auxiliary layers on the connection electrodes so as to surround the reflective layers; first electrodes on the substrate so as to surround the optical auxiliary layers and the connection electrodes and in contact with side surfaces of the connection electrodes; capping layers on the first electrodes and having openings defined to overlap the first electrodes; a light emitting stack on the first electrodes and the capping layers; and a second electrode on the light emitting stack.

According to some embodiments of the present disclosure, an electronic device includes: a display device having a resolution of 4,000 pixels per inch (PPI) or more; an optical member outside the display device and adjusting a path of light emitted from the display device; and a case accommodating the display device and the optical member, wherein the display device includes: a substrate including first and second sub-pixel areas; connection electrodes in the first and second sub-pixel areas on the substrate; reflective layers on the connection electrodes; optical auxiliary layers on the connection electrodes so as to surround the reflective layers; first electrodes on the substrate so as to surround the optical auxiliary layers and the connection electrodes and in contact with side surfaces of the connection electrodes; capping layers on the first electrodes and having openings defined to overlap the first electrodes; a light emitting stack on the first electrodes and the capping layers; and a second electrode on the light emitting stack.

According to some embodiments of the present disclosure, a method for fabricating a display device includes: forming an insulating layer on a substrate including first and second sub-pixel areas, the insulating layer having a via electrode therein; forming a connection electrode layer on the insulating layer, the connection electrode layer being connected to the via electrode; forming a preliminary reflective layer on the connection electrode layer; forming a reflective layer in each of the first and second sub-pixel areas by patterning the preliminary reflective layer; forming an auxiliary layer on the connection electrode layer so as to cover the reflective layer; forming an optical auxiliary layer and a connection electrode in each of the first and second sub-pixel areas by patterning the auxiliary layer and the connection electrode layer; forming a first electrode layer on the insulating layer so as to cover the optical auxiliary layer and the connection electrode; forming a first preliminary capping layer on the first electrode layer; forming a second preliminary capping layer and a first electrode in each of the first and second sub-pixel areas by patterning the first preliminary capping layer and the first electrode layer; forming a capping layer exposing a portion of the first electrode by forming an opening in the second preliminary capping layer; forming a light emitting stack on the first electrode and the capping layer; and forming a second electrode on the light emitting stack.

Further details according to some embodiments are described in further detail in the following detailed description and are illustrated in the drawings.

According to some embodiments, damage to a reflective layer due to hydrogen fluoride used during a cleaning process may be prevented or reduced.

For example, according to some embodiments, an optical auxiliary layer may be located between the reflective layer and a first electrode, and thus, a swelled portion of the reflective layer may not pass through a pin hole of the first electrode. Accordingly, hydrogen fluoride used during the cleaning process after the first electrode is formed may not permeate into the reflective layer. Therefore, according to some embodiments, even during the cleaning process, the damage to the reflective layer may be prevented or reduced by the optical auxiliary layer.

In addition, according to some embodiments, bonding strength between the reflective layer and the optical auxiliary layer may be relatively improved.

For example, according to some embodiments, a buffer layer may be located between the reflective layer and the optical auxiliary layer, and may relatively improve the bonding strength between the reflective layer and the optical auxiliary layer on the reflective layer by preventing or reducing an oxide film such as a silver oxide film from being formed on the reflective layer.

The characteristics of embodiments according to the present disclosure are not limited to the aforementioned characteristics, and various other characteristics will become more apparent to one of ordinary skill in the art to which embodiments according to the present disclosure pertains by referencing the detailed description of embodiments according to the present disclosure given below.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is an exploded perspective view illustrating a display device, according to some embodiments of the present disclosure;

FIG. 2 is a block diagram illustrating the display device, according to some embodiments of the present disclosure;

FIG. 3 is an equivalent circuit diagram of a first sub-pixel area, according to some embodiments of the present disclosure;

FIG. 4 is a layout diagram illustrating an example of a display panel, according to some embodiments of the present disclosure;

FIGS. 5 and 6 are layout diagrams illustrating some embodiments of a display area of FIG. 4, according to some embodiments of the present disclosure;

FIG. 7 is a cross-sectional view of an example of the display panel taken along the line I1-I1′ of FIG. 5, according to some embodiments of the present disclosure;

FIG. 8 is a cross-sectional view illustrating further details of the area A1 of FIG. 7, according to some embodiments of the present disclosure;

FIG. 9 is a cross-sectional view illustrating further details of the area A2 of FIG. 8, according to some embodiments of the present disclosure;

FIG. 10 is a cross-sectional view of an example of the display panel taken along the line I2-I2′ of FIG. 4, according to some embodiments of the present disclosure;

FIG. 11 is a cross-sectional view illustrating further details of the area A3 of FIG. 10, according to some embodiments of the present disclosure;

FIGS. 12 to 31 are views illustrating aspects of a method for fabricating a display device, according to some embodiments of the present disclosure;

FIG. 32 is a cross-sectional view of an example of the display panel taken along the line I1-I1′ of FIG. 5, according to some embodiments of the present disclosure;

FIG. 33 is a cross-sectional view illustrating further details of the area A4 of FIG. 32, according to some embodiments of the present disclosure;

FIG. 34 is a cross-sectional view illustrating further details of the area A5 of FIG. 33, according to some embodiments of the present disclosure;

FIGS. 35 to 50 are views illustrating aspects of a method for fabricating a display device, according to some embodiments of the present disclosure;

FIG. 51 is a block diagram of an electronic device, according to some embodiments of the present disclosure;

FIGS. 52 to 54 are schematic views of electronic devices, according to some embodiments of the present disclosure; and

FIG. 55 is a perspective view illustrating a head mounted display device, according to some embodiments of the present disclosure.

### DETAILED DESCRIPTION

Some embodiments of the present disclosure will now be described more fully hereinafter with reference to the accompanying drawings, in which some embodiments of the present disclosure are shown. The embodiments of the present disclosure may, however, be in different forms and should not be construed as limited to the embodiments set forth herein. Rather, the embodiments are provided so that this present disclosure will be thorough and complete, and will fully convey the scope of the embodiments to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

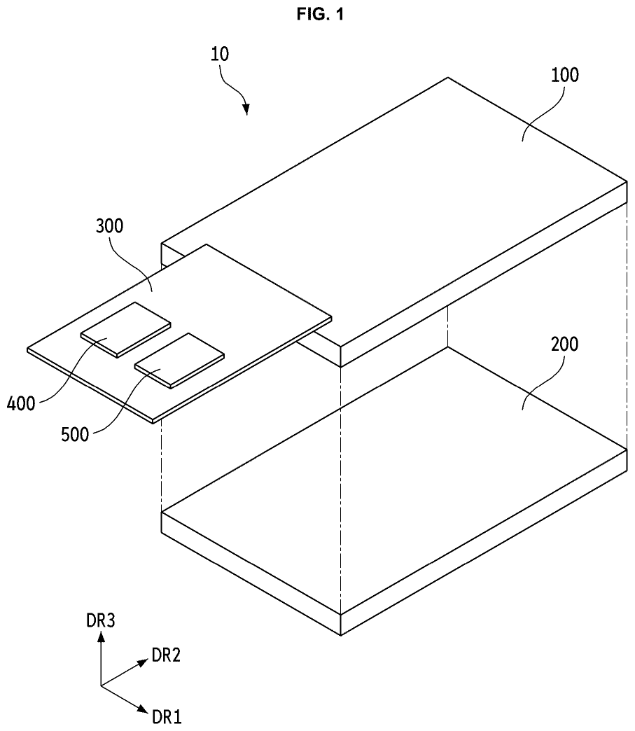

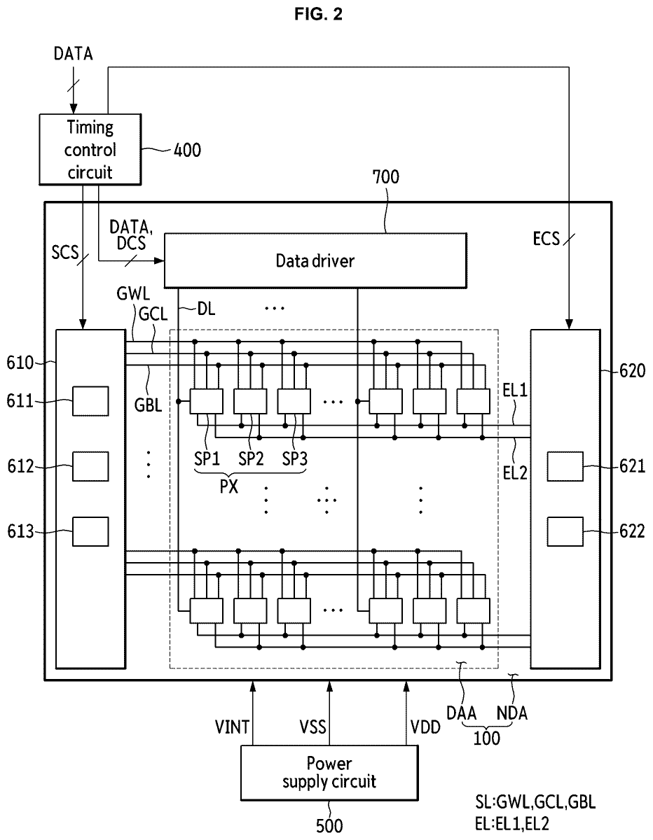

FIG. 1 is an exploded perspective view illustrating a display device according to some embodiments. FIG. 2 is a block diagram illustrating the display device according to some embodiments.

Referring to FIGS. 1 and 2, a display device 10 according to some embodiments may be a device that displays a moving image or a still image. The display device 10 according to some embodiments may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according to some embodiments may be applied as a display unit of televisions, laptop computers, monitors, billboards, or the Internet of Things (IOTs). In some embodiments, the display device 10 may be applied to smart watches, watch phones, or head mounted displays (HMDs) for implementing virtual reality and augmented reality.

The display device 10 according to some embodiments may include a display panel 100, a heat dissipation layer 200, a circuit board 300, a timing control unit 400, and a power supply circuit 500.

The display panel 100 may have a shape similar to a rectangular shape in a plan view. For example, the display panel 100 may have a shape similar to a rectangular shape, in the plan view, having short sides in a first direction DR1 (e.g., length in the x-axis direction of FIG. 1) and long sides in a second direction DR2 (e.g., height in the y-axis direction of FIG. 1) crossing the first direction DR1. In the display panel 100, a corner where the short side in the first direction DR1 and the long side in the second direction DR2 meet may be rounded with a selected curvature or right-angled. A shape of the display panel 100 in the plan view is not limited to the rectangular shape, and may be a shape similar to other polygonal shapes, a circular shape, an elliptical shape, or an irregular. A shape of the display device 10 in the plan view may follow the shape of the display panel 100 in the plan view, but some embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA that displays images and a non-display area NDA that does not display images, as illustrated in FIG. 2.

The plurality of pixels PX may be located (e.g., arranged, positioned, or located) in the display area DAA. The plurality of pixels PX may be arranged in a matrix form in the first direction DR1 and the second direction DR2. The plurality of scan lines SL and the plurality of emission control lines EL may extend in the first direction DR1 and may be arranged in the second direction DR2. The plurality of data lines DL may extend in the second direction DR2 and may be arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

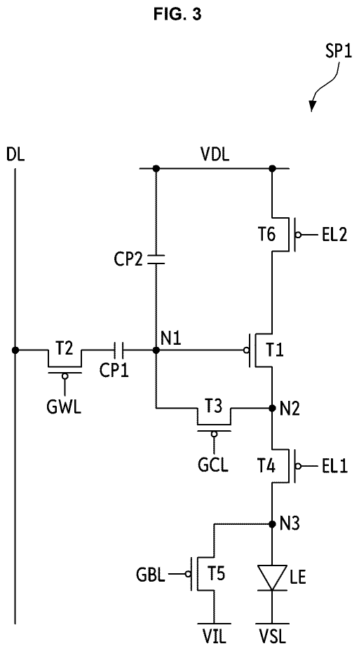

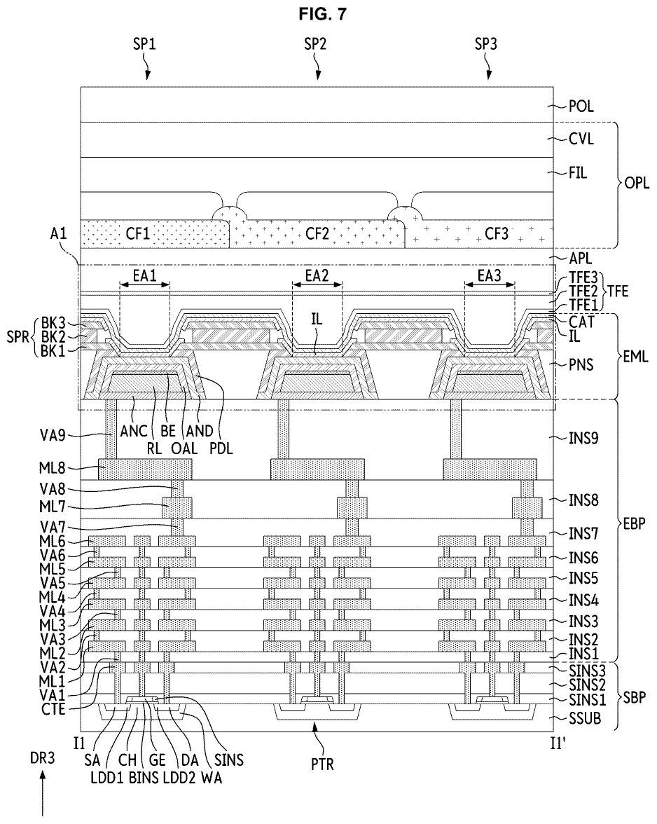

The plurality of pixels PX may include a plurality of sub-pixel areas SP1, SP2, and SP3. The plurality of sub-pixel areas SP1, SP2, and SP3 may include a plurality of pixel transistors T1 to T6 as illustrated in FIG. 3, and the plurality of pixel transistors may be formed by a semiconductor process and located on a semiconductor substrate SSUB (see FIG. 7). For example, a plurality of pixel transistors of the data driver 700 may be formed as complementary metal oxide semiconductors (CMOS) transistors, but some embodiments of the present disclosure are not limited thereto.

Each of (e.g., one or more of) the plurality of sub-pixel areas SP1, SP2, and SP3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of sub-pixel areas SP1, SP2, and SP3 may receive a data voltage of (e.g., provided by) the data line DL according to a write scan signal of the write scan line GWL, and allow a light emitting element to emit light according to the data voltage.

The scan driver 610, the emission driver 620, and the data driver 700 may be located in the non-display area NDA.

The scan driver 610 may include a plurality of scan transistors, and the emission driver 620 may include a plurality of light emitting transistors. The plurality of scan transistors and the plurality of light emitting transistors may be formed by a semiconductor process and formed on the semiconductor substrate SSUB (see FIG. 7). For example, the plurality of scan transistors and the plurality of light emitting transistors may be formed as CMOS transistors, but some embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially (e.g., in an order) output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 may include a first emission control driver 621 and a second emission control driver 622. Each of the first emission control driver 621 and the second emission control driver 622 may receive an emission timing control signal ECS from the timing control unit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and formed on the semiconductor substrate SSUB (see FIG. 7). For example, the plurality of data transistors may be formed as CMOS transistors, but some embodiments of the present disclosure are not limited thereto.

The data driver 700 may receive digital video data DATA and a data timing control signal DCS from the timing control circuit 400. The data driver 700 may convert the digital video data DATA into analog data voltages according to the data timing control signal DCS and outputs the analog data voltages to the data lines DL. In this case, the sub-pixel areas SP1, SP2, and SP3 may be selected by the write scan signals of the scan driver 610, and the data voltages may be supplied to the selected sub-pixel areas SP1, SP2, and SP3.

The heat dissipation layer 200 may overlap the display panel 100 in a third direction DR3 (e.g., width in the x-axis direction of FIG. 1), which is a thickness direction of the display panel 100. The heat dissipation layer 200 may be located on one surface, for example, a rear surface, of the display panel 100. The heat dissipation layer 200 may serve to dissipate heat generated from the display panel 100. The heat dissipation layer 200 may include a layer made of graphite or metal such as silver (Ag), copper (Cu), or aluminum (Al) having a relatively high thermal conductivity.

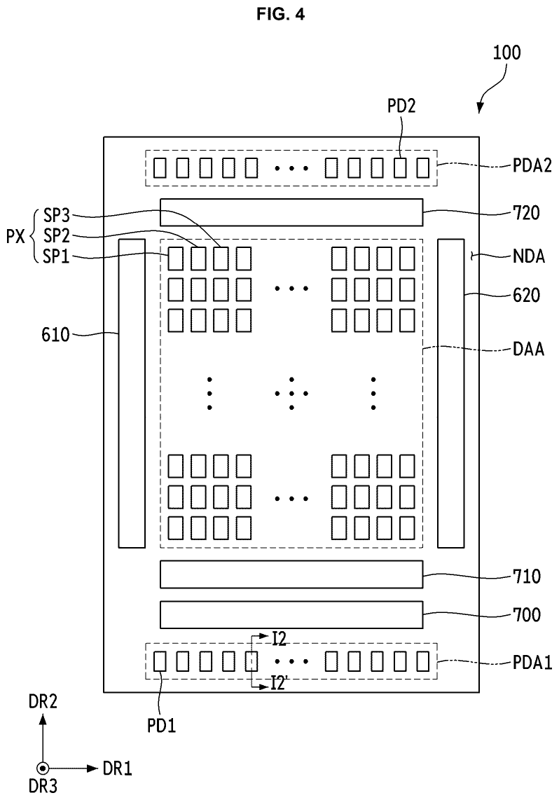

The circuit board 300 may be electrically connected to a plurality of first pads PD1 (see FIG. 4) of a first pad unit PDA1 (see FIG. 4) of the display panel 100 using a conductive adhesive member such as an anisotropic conductive film. The circuit board 300 may be a flexible printed circuit board or a flexible film having a flexible material. It is illustrated in FIG. 1 that the circuit board 300 is unbent, but the circuit board 300 may be bent in some embodiments. In this case, one end of the circuit board 300 may be located on the rear surface of the display panel 100 and/or a rear surface of the heat dissipation layer 200. The other end of the circuit board 300 may be connected to the plurality of first pads PD1 (see FIG. 4) of the first pad unit PDA1 (see FIG. 4) of the display panel 100 using the conductive adhesive member. One end of the circuit board 300 may be an end opposite to the other end of the circuit board 300. For example, the circuit board 300 may have ends that are opposite and distal.

The timing control unit 400 may receive digital video data and timing signals from the outside (e.g., external to the display panel 100). The timing control circuit 400 may generate the scan timing control signal SCS, the emission timing control signal ECS, and the data timing control signal DCS for controlling the display panel 100 according to the timing signals. The timing control unit 400 may output the scan timing control signal SCS to the scan driver 610 and output the emission timing control signal ECS to the emission driver 620. The timing control unit 400 may output the digital video data DATA and the data timing control signal DCS to the data driver 700.

The power supply circuit 500 may generate a plurality of panel driving voltages according to an external source voltage. For example, the power supply circuit 500 may generate a first driving voltage VSS, a second driving voltage VDD, and a third driving voltage VINT and supply the first driving voltage VSS, the second driving voltage VDD, and the third driving voltage VINT to the display panel 100. The first driving voltage VSS, the second driving voltage VDD, and the third driving voltage VINT will be described in more detail later with reference to FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control unit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

In some embodiments, each of the timing control circuit 400 and the power supply circuit 500 may be located in the non-display area NDA of the display panel 100, similar to the scan driver 610, the emission driver 620, and the data driver 700. In this case, the timing control circuit 400 may include a plurality of timing transistors, and the power supply circuit 500 may include a plurality of power transistors. The plurality of timing transistors and the plurality of power transistors may be formed by a semiconductor process and formed on the semiconductor substrate SSUB (see FIG. 7). For example, the plurality of timing transistors and the plurality of power transistors may be formed as CMOS transistors, but some embodiments of the present disclosure are not limited thereto. Each of the timing control circuit 400 and the power supply circuit 500 may be located between the data driver 700 and the first pad unit PDA1 (see FIG. 4).

FIG. 3 is an equivalent circuit diagram of a first sub-pixel area according to some embodiments. Although FIG. 3 illustrates various components in a sub-pixel according to some embodiments, embodiments according to the present disclosure are not limited thereto, and according to various embodiments, the sub-pixel may include additional components, or fewer components, without departing from the spirt and scope of embodiments according to the present disclosure.

Referring to FIG. 3, a first sub-pixel area SP1 may be connected to a write scan line GWL, a control scan line GCL, a bias scan line GBL, a first emission control line EL1, a second emission control line EL2, and a data line DL. In addition, the first sub-pixel area SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first sub-pixel area SP1 may include a plurality of transistors T1 to T6, a light emitting element LE, a first capacitor CP1, and a second capacitor CP2.

The light emitting element LE may emit light according to a driving current Ids flowing through a channel of a first transistor T1. An amount of light emitted from the light emitting element LE may be proportional to the driving current Ids. The light emitting element LE may be located between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer located between the first electrode and the second electrode, but embodiments of the present disclosure are not limited thereto. For example, the light emitting element LE may be an inorganic light emitting element including a first electrode, a second electrode, and an inorganic semiconductor located between the first electrode and the second electrode, and in this case, the light emitting element LE may be a micro light emitting diode.

The first transistor T1 may be a driving transistor controlling a source-drain current Ids (hereinafter referred to as a “driving current”) flowing between a source electrode and a drain electrode according to a voltage applied to a gate electrode thereof. The first transistor T1 may include the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 may be turned on by a write scan signal of the write scan line GWL to connect one electrode of the first capacitor CP1 to the data line DL. For this reason, a data voltage of the data line DL may be applied to one electrode of the first capacitor CP1. The second transistor T2 may include a gate electrode connected to the write scan line GWL, a source electrode connected to the data line DL, and a drain electrode connected to one electrode of the first capacitor CP1.

A third transistor T3 may be located between the first node N1 and the second node N2. The third transistor T3 may be turned on by a control scan signal of the control scan line GCL to connect the first node N1 to the second node N2. For this reason, when the gate electrode and the drain electrode of the first transistor T1 are connected to each other, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by a first emission control signal of the first emission control line EL1 to connect the second node N2 to the third node N3. For this reason, the driving current of the first transistor T1 may be supplied to the light emitting element LE. The fourth transistor T4 may include a gate electrode connected to the first emission control line EL1, a source electrode connected to the second node N2, and the drain electrode connected to the third node N3.

A fifth transistor T5 may be located between the third node N3 and the third driving voltage line VIL. The fifth transistor T5 may be turned on by a bias scan signal of the bias scan line GBL to connect the third node N3 to the third driving voltage line VIL. For this reason, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 may be turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and the drain electrode connected to the source electrode of the first transistor T1.

The first capacitor CP1 may be formed between the first node N1 and the drain electrode of the second transistor T2. The first capacitor CP1 may include one electrode connected to the drain electrode of the second transistor T2 and the other electrode connected to the first node N1.

The second capacitor CP2 may be formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a contact point between the gate electrode of the first transistor T1, the drain electrode of the third transistor T3, the other electrode of the first capacitor CP1, and one electrode of the second capacitor CP2. The second node N2 may be a contact point between the drain electrode of the first transistor T1, the source electrode of the third transistor T3, and the source electrode of the fourth transistor T4. The third node N3 may be a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but some embodiments of the present disclosure are not limited thereto. Each of the first to sixth transistors T1 to T6 may be an N-type MOSFET. According to some embodiments, some of the first to sixth transistors T1 to T6 may be P-type MOSFETs, and the others of the first to sixth transistors T1 to T6 may be N-type MOSFETs.

It is illustrated in FIG. 3 that the first sub-pixel area SP1 may include six transistors T1 to T6 and two capacitors C1 and C2, but it is to be noted that an equivalent circuit diagram of the first sub-pixel area SP1 is not limited to the example illustrated in FIG. 3. For example, the numbers of transistors and capacitors of the first sub-pixel area SP1 are not limited to those illustrated in FIG. 3, in some embodiments.

In addition, an equivalent circuit diagram of the second sub-pixel area SP2 and an equivalent circuit diagram of the third sub-pixel area SP3 may be the same (or substantially the same) as the equivalent circuit diagram of the first sub-pixel area SP1 described with reference to FIG. 3. Therefore, a description of the equivalent circuit diagram of the second sub-pixel area SP2 and the equivalent circuit diagram of the third sub-pixel area SP3 is omitted in the present disclosure.

FIG. 4 is a layout diagram illustrating an example of a display panel according to some embodiments.

Referring to FIG. 4, the display area DAA of the display panel 100 according to some embodiments may include a plurality of pixels PX arranged in a matrix form. The non-display area NDA of the display panel 100 according to some embodiments may include a scan driver 610, an emission driver 620, a data driver 700, a first distribution circuit 710, a second distribution circuit 720, a first pad unit PDA1, and a second pad unit PDA2.

The scan driver 610 may be located on a first side of the display area DAA, and the emission driver 620 may be located on a second side of the display area DAA. For example, the scan driver 610 may be located on one side of the display area DAA in the first direction DR1 (x-axis direction of FIG. 4), and the emission driver 620 may be located on the other side of the display area DAA in the first direction DR1. For example, the scan driver 610 may be located on the left side of the display area DAA, and the emission driver 620 may be located on the right side of the display area DAA. However, some embodiments of the present disclosure are not limited thereto, and the scan drivers 610 and the emission drivers 620 may be located on both the first and second sides of the display area DAA.

The first pad unit PDA1 may include a plurality of first pads PD1 connected to pads or bumps of the circuit board 300 through a conductive adhesive member. The first pad unit PDA1 may be located on a third side of the display area DAA. For example, the first pad unit PDA1 may be located on one side of the display area DAA in the second direction DR2 (y-axis direction of FIG. 4). The first pad unit PDA1 may be located outside of the data driver 700 in the second direction DR2. For example, the first pad unit PDA1 may be located closer to an edge of the display panel 100 than the data driver 700 is.

The second pad unit PDA2 may include a plurality of second pads PD2 corresponding to inspection pads that may be used to inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The second pad unit PDA2 may be located on a fourth side of the display area DAA. For example, the second pad unit PDA2 may be located on the other side of the display area DAA in the second direction DR2. The second pad unit PDA2 may be located outside of the second distribution circuit 720 in the second direction DR2. For example, the second pad unit PDA2 may be located closer to an edge of the display panel 100 than the second distribution circuit 720 is.

The first distribution circuit 710 may distribute data voltages applied through the first pad unit PDA1 to the plurality of data lines DL. For example, the first distribution circuit 710 may distribute data voltages applied through one first pad PD1 of the first pad unit PDA1 to P number of data lines DL (P is a positive integer of 2 or more), and for this reason, the number of first pads PD1 may be relatively reduced. The first distribution circuit 710 may be located on the third side of the display area DAA of the display panel 100. For example, the first distribution circuit 710 may be located on one side of the display area DAA in the second direction DR2. For example, the first distribution circuit 710 may be located on the lower side of the display area DAA.

The second distribution circuit 720 may distribute signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be located on the fourth side of the display area DAA of the display panel 100. For example, the second distribution circuit 720 may be located on the other side of the display area DAA in the second direction DR2. For example, the second distribution circuit 720 may be located on the upper side of the display area DAA.

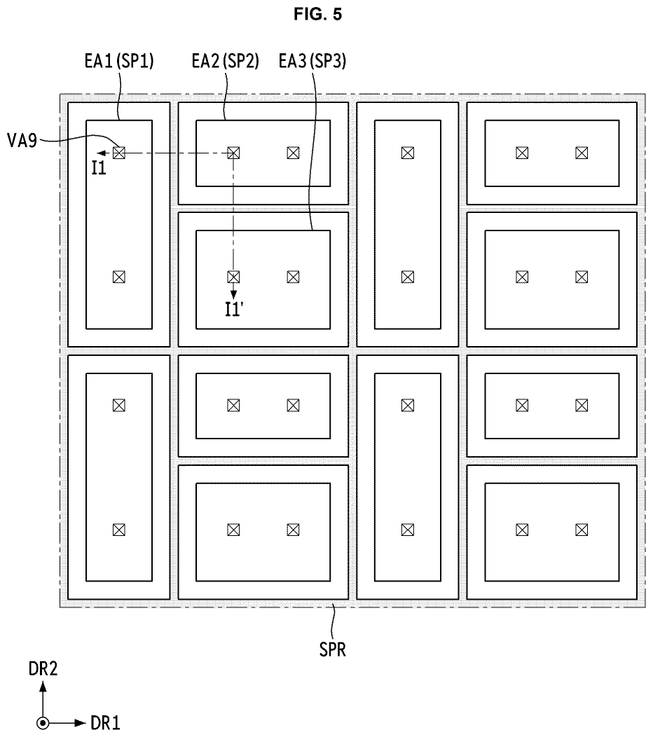

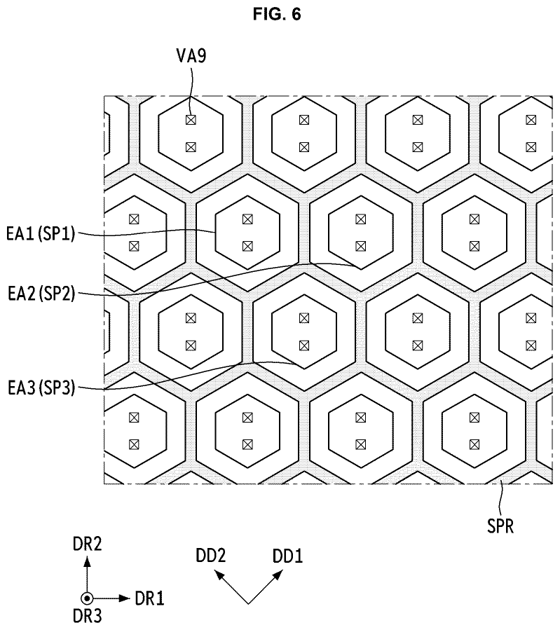

FIGS. 5 and 6 are layout diagrams illustrating some embodiments of a display area DAA of FIG. 4.

Referring to FIGS. 5 and 6, each of the plurality of pixels PX may include a first emission area EA1 that is an emission area of the first sub-pixel area SP1, a second emission area EA2 that is an emission area of the second sub-pixel area SP2, and a third emission area EA3 that is an emission area of the third sub-pixel area SP3.

Each of the first emission area EA1, the second emission area EA2, and the third emission area EA3 may have a polygonal shape, a circular shape, an elliptical shape, or an irregular shape in a plan view.

A maximum length of the first emission area EA1 in the first direction DR1 may be smaller than a maximum length of the second emission area EA2 in the first direction DR1 (x-axis direction of FIG. 5) and a maximum length of the third emission area EA3 in the first direction DR1. The maximum length of the second emission area EA2 in the first direction DR1 and the maximum length of the third emission area EA3 in the first direction DR1 may be the same (or substantially the same) as each other.

A maximum length of the first emission area EA1 in the second direction DR2 (y-axis direction of FIG. 5) may be greater than a maximum length of the second emission area EA2 in the second direction DR2 and a maximum length of the third emission area EA3 in the second direction DR2. The maximum length of the second emission area EA2 in the second direction DR2 may be smaller than the maximum length of the third emission area EA3 in the second direction DR2. The maximum length of the first emission area EA1 in the second direction DR2 may be greater than the maximum length of the second emission area EA2 in the second direction DR2.

Each of the first emission area EA1, the second emission area EA2, and the third emission area EA3 may have a hexagonal shape including six straight lines, in the plan view, as illustrated in FIG. 6, but some embodiments of the present disclosure are not limited thereto. Each of the first emission area EA1, the second emission area EA2, and the third emission area EA3 may have polygonal shapes other than the hexagonal shape, a circular shape, an elliptical shape, or an irregular shape in the plan view.

As illustrated in FIG. 5, in each of the plurality of pixels PX, the first emission area EA1 and the second emission area EA2 may neighbor (e.g., adjacent) to each other in the first direction DR1. In addition, the first emission area EA1 and the third emission area EA3 may neighbor to each other in the first direction DR1. In addition, the second emission area EA3 and the third emission area EA3 may neighbor to each other in the second direction DR2. An area of the first emission area EA1, an area of the second emission area EA2, and an area of the third emission area EA3 may be different from each other.

In some embodiments, as illustrated in FIG. 6, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 may be a direction between the first direction DR1 and the second direction DR2 and may refer to a direction inclined (e.g., angled) by 45° with respect to the first direction DR1 and the second direction DR2, and the second diagonal direction DD2 may be a direction orthogonal to the first diagonal direction DD1.

The first sub-pixel area SP1 may emit a first light that has passed through a first color filter CF1 (see FIG. 7) among light emitted from the first emission area EA1, the second sub-pixel area SP2 may emit a second light that has passed through a second color filter CF2 (see FIG. 7) among light emitted from the second emission area EA2, and the third sub-pixel area SP3 may emit a third light that has passed through a third color filter CF3 (see FIG. 7) among light emitted from the third emission area EA3.

The first light, the second light, and the third light described above may be light of different wavelength bands. For example, one of the first light, the second light, and the third light may be light of a blue wavelength band, another of the first light, the second light, and the third light may be light of a green wavelength band, and the other of the first light, the second light, and the third light may be light of a red wavelength band. Here, the light of the blue wavelength band may indicate that a main peak wavelength of the light is included in a wavelength band of 370 nanometers (nm) to 460 nm (or approximately 370 nanometers (nm) to 460 nm), the light of the green wavelength band may indicate that a main peak wavelength of the light is included in a wavelength band of 480 nm to 560 nm (or approximately 480 nm to 560 nm), and the light of the red wavelength band may indicate that a main peak wavelength of the light is included in a wavelength band of 600 nm to 750 nm (or approximately 600 nm to 750 nm).

It is illustrated in FIGS. 5 and 6 that each of the plurality of pixels PX may include three emission areas EA1, EA2, and EA3, but some embodiments of the present disclosure are not limited thereto. For example, each of the plurality of pixels PX may also include four emission areas.

In addition, an arrangement of the emission areas of the plurality of pixels PX is not limited to those illustrated in FIGS. 5 and 6. For example, the emission areas of the plurality of pixels PX may be arranged in a stripe structure in which the emission areas are arranged in the first direction DR1, a PenTile® structure in which each of the emission areas has a diamond arrangement, or a hexagonal structure in which the emission areas having a hexagonal shape in a plan view are arranged as illustrated in FIG. 6.

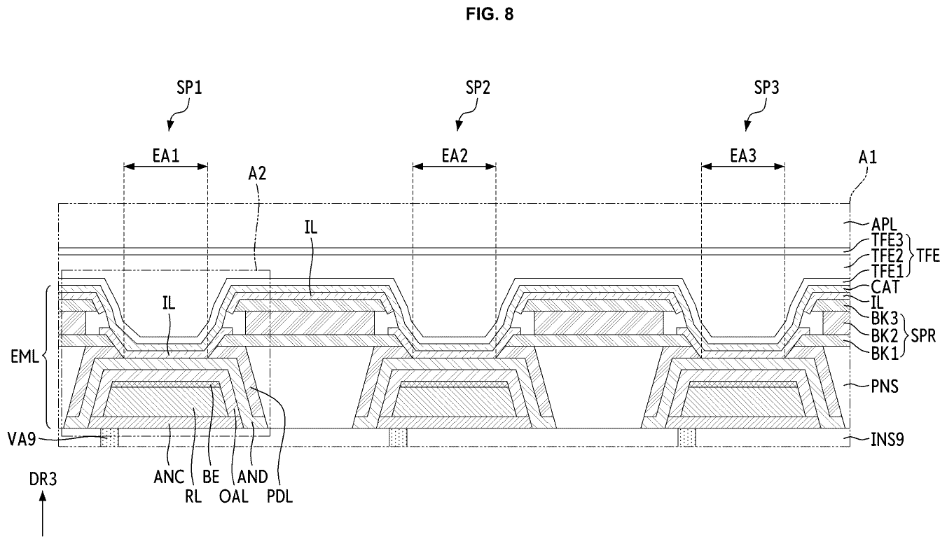

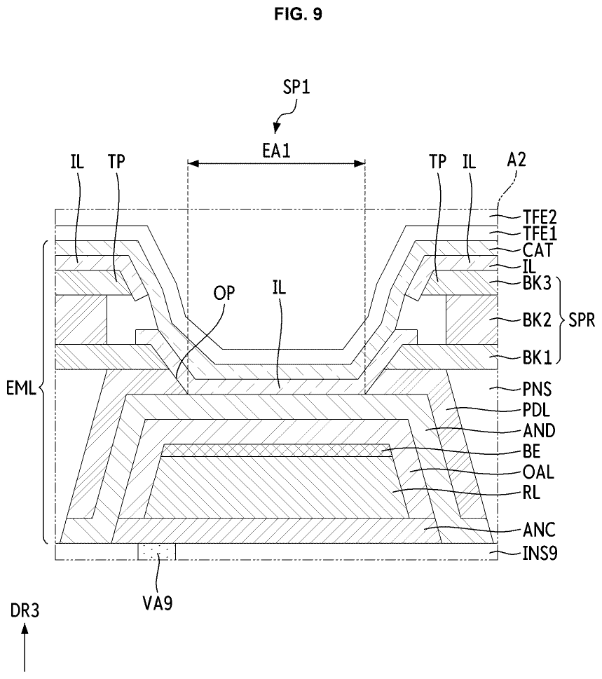

FIG. 7 is a cross-sectional view of an example of the display panel 100 taken along the line I1-I1′ of FIG. 5. FIG. 8 is a cross-sectional view illustrating further details of the area A1 of FIG. 7, and FIG. 9 is a cross-sectional view illustrating further details of the area A2 of FIG. 8.

Referring to FIGS. 7 to 9, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating layers SINS1, SINS2, SINS3 covering the plurality of pixel transistors PTR, and a plurality of contact terminals CTE electrically connected respectively to the plurality of pixel transistors PTR. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with first-type impurities. A plurality of well regions WA may be located in an upper surface of the semiconductor substrate SSUB. The plurality of well regions WA may be regions doped with second-type impurities. The second-type impurities may be different from the first-type impurities described above. For example, when the first-type impurities are p-type impurities, the second-type impurities may be n-type impurities. In some embodiments, when the first-type impurities are n-type impurities, the second-type impurities may be p-type impurities.

Each of the plurality of well regions WA may include a source region SA corresponding to a source electrode of the pixel transistor PTR, a drain region DA corresponding to a drain electrode of the pixel transistor PTR, and a channel region CH located between the source region SA and the drain region DA.

A bottom insulating layer BINS may be located between a gate electrode GE and the well region WA. Side surface insulating layers SINS may be located on side surfaces of the gate electrode GE. The side surface insulating layers SINS may be located on the bottom insulating layer BINS.

Each of the source region SA and the drain region DA may be a region doped with the first-type impurities. The gate electrode GE of the pixel transistor PTR may overlap the well region WA in the third direction DR3 (e.g., vertical direction in FIG. 7), which is a thickness direction of the semiconductor substrate SSUB. The channel region CH may overlap the gate electrode GE in the third direction DR3. The source region SA may be located on one side of the gate electrode GE, and the drain region SA may be located on the other side of the gate electrode GE.

Each of the plurality of well regions WA may further include a first low-concentration impurity region LDD1 located between the channel region CH and the source region SA and a second low-concentration impurity region LDD2 located between the channel region CH and the drain region DA. The first low-concentration impurity region LDD1 may be a region having a lower impurity concentration than the source region SA due to the bottom insulating layer BINS. The second low-concentration impurity region LDD2 may be a region having a lower impurity concentration than the drain region DA due to the bottom insulating layer BINS. A distance between the source region SA and the drain region DA may increase by the first low-concentration impurity region LDD1 and the second low-concentration impurity region LDD2. For example, the distance between the source region SA and the drain region DA may increase as an area of the first low-concentration impurity region LDD1 and the second low-concentration impurity region LDD2 increases. Therefore, a length of the channel region CH of each of the pixel transistors PTR may increase, and thus, punch-through and hot carrier phenomena caused by a short channel may be prevented or reduced.

A first semiconductor insulating layer SINS1 may be located on the semiconductor substrate SSUB. The first semiconductor insulating layer SINS1 may be formed as a silicon carbonitride (SiCN) or silicon oxide (SiOₓ)-based inorganic film, but some embodiments of the present disclosure are not limited thereto.

A second semiconductor insulating layer SINS2 may be located on the first semiconductor insulating layer SINS1. The second semiconductor insulating layer SINS2 may be formed as a silicon oxide (SiOₓ)-based inorganic film, but some embodiments of the present disclosure are not limited thereto.

The plurality of contact terminals CTE may be located on the second semiconductor insulating layer SINS2. Each of the plurality of contact terminals CTE may be connected to any one of the gate electrode GE, the source region SA, and the drain region DA of each of the pixel transistors PTR through a hole penetrating through the first semiconductor insulating layer SINS1 and the second semiconductor insulating layer SINS2. Each of the plurality of contact terminals CTE may be made of any one of copper (Cu), aluminum (Al), tungsten (W), molybdenum (Mo), chromium (Cr), gold (Au), titanium (Ti), nickel (Ni), and neodymium (Nd), or alloys thereof.

A third semiconductor insulating layer SINS3 may be located on side surfaces of each of the plurality of contact terminals CTE. An upper surface of each of the plurality of contact terminals CTE may be exposed (e.g., uncovered) without being covered by the third semiconductor insulating layer SINS3. The third semiconductor insulating layer SINS3 may be formed as a silicon oxide (SiOₓ)-based inorganic film, but embodiments of the present disclosure are not limited thereto.

The semiconductor substrate SSUB may be replaced with a glass substrate or a polymer resin substrate such as a polyimide substrate. In this case, thin film transistors may be located on the glass substrate or the polymer resin substrate. The glass substrate may be a rigid substrate that is not bent, and the polymer resin substrate may be a flexible substrate that may be bent or curved.

The light emitting element backplane EBP may include a plurality of conductive layers ML1 to ML8, a plurality of via electrodes VA1 to VA9, and a plurality of insulating layers INS1 to INS9. In addition, the light emitting element backplane EBP may include a plurality of insulating layers INS1 to INS9 located between first to eighth conductive layers ML1 to ML8. For example, insulating layer INS2 may be located between conductive layer conductive layers ML1 and ML2, insulating layer INS3 may be located between conductive layers ML2 and ML3, and so on.

The first to eighth conductive layers ML1 to ML8 may serve to implement a circuit of the first sub-pixel area SP1 illustrated in FIG. 3 by connecting the plurality of contact terminals CTE exposed from the semiconductor backplane SBP to each other. For example, only the first to sixth transistors T1 to T6 may be formed in the semiconductor backplane SBP, and the connection between the first to sixth transistors T1 to T6 and the formation of the first capacitor CP1 and the second capacitor CP2 are performed through the first to eighth conductive layers ML1 to ML8. In addition, the connection between a drain region corresponding to the drain electrode of the fourth transistor T4, a source region corresponding to the source electrode of the fifth transistor T5, and a first electrode AND of the light emitting element LE also may be performed through the first to eighth conductive layers ML1 to ML8.

A first insulating layer INS1 may be located on the semiconductor backplane SBP. Each of first via electrodes VA1 may penetrate through the first insulating layer INS1 to be connected to the contact terminal CTE exposed from the semiconductor backplane SBP. Each of the first conductive layers ML1 may be located on the first insulating layer INS1 and connected to the first via electrode VA1.

A second insulating layer INS2 may be located on the first insulating layer INS1 and the first conductive layers ML1. Each of second via electrodes VA2 may penetrate through the second insulating layer INS2 to be connected to the exposed first conductive layer ML1. Each of the second conductive layers ML2 may be located on the second insulating layer INS2 and connected to the second via electrode VA2.

A third insulating layer INS3 may be located on the second insulating layer INS2 and the second conductive layers ML2. Each of third via electrodes VA3 may penetrate through the third insulating layer INS3 to be connected to the exposed second conductive layer ML2. Each of the third conductive layers ML3 may be located on the third insulating layer INS3 and connected to the third via electrode VA3.

A fourth insulating layer INS4 may be located on the third insulating layer INS3 and the third conductive layers ML3. Each of fourth via electrodes VA4 may penetrate through the fourth insulating layer INS4 to be connected to the exposed third conductive layer ML3. Each of the fourth conductive layers ML4 may be located on the fourth insulating layer INS4 and connected to the fourth via electrode VA4.

A fifth insulating layer INS5 may be located on the fourth insulating layer INS4 and the fourth conductive layers ML4. Each of fifth via electrodes VA5 may penetrate through the fifth insulating layer INS5 to be connected to the exposed fourth conductive layer ML4. Each of the fifth conductive layers ML5 may be located on the fifth insulating layer INS5 and connected to the fifth via electrode VA5.

A sixth insulating layer INS6 may be located on the fifth insulating layer INS5 and the fifth conductive layers ML5. Each of sixth via electrodes VA6 may penetrate through the sixth insulating layer INS6 to be connected to the exposed fifth conductive layer ML5. Each of the sixth conductive layers ML6 may be located on the sixth insulating layer INS6 and connected to the sixth via electrode VA6.

A seventh insulating layer INS7 may be located on the sixth insulating layer INS6 and the sixth conductive layers ML6. Each of seventh via electrodes VA7 may penetrate through the seventh insulating layer INS7 to be connected to the exposed sixth conductive layer ML6. Each of the seventh conductive layers ML7 may be located on the seventh insulating layer INS7 and connected to the seventh via electrode VA7.

An eighth insulating layer INS8 may be located on the seventh insulating layer INS7 and the seventh conductive layers ML7. Each of eighth via electrodes VA8 may penetrate through the eighth insulating layer INS8 to be connected to the exposed seventh conductive layer ML7. Each of the eight conductive layers ML8 may be located on the eighth insulating layer INS8 and connected to the eighth via electrode VA8.

The first to eighth conductive layers ML1 to ML8 and the first to eighth via electrodes VA1 to VA8 may be made of the same (or substantially the same) material. Each of the first to eighth conductive layers ML1 to ML8 and the first to eighth via electrodes VA1 to VA8 may be made of any one of copper (Cu), aluminum (Al), tungsten (W), molybdenum (Mo), chromium (Cr), gold (Au), titanium (Ti), nickel (Ni), and neodymium (Nd), or alloys thereof. The first to eighth via electrodes VA1 to VA8 may be made of the same (or substantially the same) material. The first to eighth insulating layers INS1 to INS8 may be formed as silicon oxide (SiOₓ)-based inorganic films, but some embodiments of the present disclosure are not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via electrode VA1, a thickness of the second via electrode VA2, a thickness of the third via electrode VA3, a thickness of the fourth via electrode VA4, a thickness of the fifth via electrode VA5, and a thickness of the sixth via electrode VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be the same (or substantially the same) as each other. For example, the thickness of the first conductive layer ML1 may be 1,360 angstrom (Å) (or approximately 1,360 angstrom (Å)), each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be 1,440 Å (or approximately 1,440 Å), and each of the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6 may be 1,150 Å (or approximately 1,150 Å).

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the thickness of the eighth conductive layer ML8 may be greater than each of a thickness of the seventh via electrode VA7 and a thickness of the eighth via electrode VA8. Each of the thickness of the seventh via electrode VA7 and the thickness of the eighth via electrode VA8 may be greater than each of the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6. The thickness of the seventh conductive layer ML7 and the thickness of the eighth conductive layer ML8 may be the same (or substantially the same) as each other. For example, each of the thickness of the seventh conductive layer ML7 and the thickness of the eighth conductive layer ML8 may be 9,000 Å (or approximately 9,000 Å). Each of the thickness of the seventh via electrode VA7 and the thickness of the eighth via electrode VA8 may be 6,000 Å (or approximately 6,000 Å).

A ninth insulating layer INS9 may be located on the eighth insulating layer INS8 and the eighth conductive layer ML8. The ninth insulating layer INS9 may be formed as a silicon oxide (SiOₓ)-based inorganic film, but some embodiments of the present disclosure are not limited thereto.

Each of ninth via electrodes VA9 may penetrate through the ninth insulating layer INS9 to be connected to the exposed eighth conductive layer ML8. Each of the ninth via electrodes VA9 may be made of any one of copper (Cu), aluminum (Al), tungsten (W), molybdenum (Mo), chromium (Cr), gold (Au), titanium (Ti), nickel (Ni), and neodymium (Nd), or alloys thereof. A thickness of the ninth via electrode VA9 may be 16,500 Å (or approximately 16,500 Å).

The display element layer EML may be located on the light emitting element backplane EBP. The display element layer EML may include a plurality of connection electrodes ANC, a plurality of reflective layers RL, a planarization film PNS, a plurality of capping layers PDL, a plurality of first electrodes AND, a light emitting stack IL, a second electrode CAT, and a plurality of separators SPR.

In addition, the display element layer EML may include a first emission area EA1, a second emission area EA2, and a third emission area EA3. Each of the first emission area EA1, the second emission area EA2, and the third emission area EA3 may be an area where the first electrode AND, the light emitting stack IL, and the second electrode CAT are sequentially stacked. Each of the first emission area EA1, the second emission area EA2, and the third emission area EA3 may be an area where a light emitting element LE including the first electrode AND, the light emitting stack IL, and the second electrode CAT are located. Each of the first emission area EA1, the second emission area EA2, and the third emission area EA3 may be partitioned by the capping layer PDL.

The plurality of connection electrodes ANC may be located on the ninth insulating layer INS9. For example, the plurality of connection electrodes ANC may be located on the ninth insulating layer INS9 so as to be connected to a plurality of ninth via electrodes VA9, respectively. Each of the plurality of connection electrodes ANC may be made of titanium (Ti), titanium nitride (TiN), or transparent conductive oxide. For example, the transparent conductive oxide may be indium tin oxide (ITO) or indium zinc oxide (IZO), but some embodiments of the present disclosure are not limited thereto.

The plurality of reflective layers RL may be located on the plurality of connection electrodes ANC, respectively. For example, the reflective layers RL may be located between the connection electrodes ANC and buffer layers BE, respectively. Each of the reflective layers RL may be made of any one of copper (Cu), aluminum (Al), silver (Ag), tungsten (W), molybdenum (Mo), chromium (Cr), gold (Au), titanium (Ti), nickel (Ni), and neodymium (Nd), or alloys thereof. For example, each of the reflective layers RL may include aluminum (Al) or silver (Ag). The connection electrode ANC may have a greater area than an area of the reflective layer RL. For example, in a plan view, an area of the connection electrode ANC may be greater than an area of the reflective layer RL so that an edge of the connection electrode ANC surrounds the reflective layer RL.

The buffer layers BE may be located on the reflective layers RL, respectively. The buffer layer BE may be located on an upper surface of the reflective layer RL. The buffer layer BE may be in contact (or in direct contact) with the reflective layer RL. The buffer layer BE may prevent or reduce an oxide film being formed on the reflective layer RL. For example, when the reflective layer RL is made of a material including silver (Ag), an oxide film such as a silver oxide (AgO) film may be formed on the reflective layer RL. Because such an oxide film may have an irregular surface, when a heterogeneous layer (e.g., an optical auxiliary layer OAL) is formed on the reflective layer RL, bonding strength between the reflective layer RL and the heterogeneous layer may be weakened. In such a case, the heterogeneous layer on the reflective layer RL may not be bonded to the reflective layer, and may be lifted from the reflective layer RL. The buffer layer BE may relatively improve the bonding strength between the reflective layer RL and the heterogeneous layer on the reflective layer RL by preventing or reducing the oxide film such as the silver oxide film being formed on the reflective layer RL. The buffer layer BE may have a thickness smaller than (or equal to) 10 Å (or approximately 10 Å). The buffer layer BE may include titanium nitride (TiN). The buffer layer BE may be made of the same material as the connection electrode ANC.

The optical auxiliary layers OAL may be located on the buffer layers BE, respectively. For example, the optical auxiliary layer OAL may be located on an upper surface of the buffer layer BE, side surfaces of the buffer layer BE, and side surfaces of the reflective layer RL. The optical auxiliary layer OAL may be in contact (or in direct contact) with each of the upper surface of the buffer layer BE, the side surfaces of the buffer layer BE, and the side surfaces of the reflective layer RL. In addition, the optical auxiliary layer OAL may be located on an edge of the connection electrode ANC. The optical auxiliary layer OAL may be in contact (or in direct contact) with an edge of an upper surface of the connection electrode ANC. The optical auxiliary layer OAL may surround the upper surface and the side surfaces of the reflective layer RL. In this case, the optical auxiliary layer OAL may completely surround the reflective layer RL together with the connection electrode ANC. For example, in a cross section, the reflective layer RL may be completely surrounded by the optical auxiliary layer OAL and the connection electrode ANC. In some embodiments, the reflective layer RL may be completely surrounded by the optical auxiliary layer OAL, the buffer layer BE, and the connection electrode ANC. The optical auxiliary layer OAL may have a thickness smaller than (or equal to) 100 Å (or approximately 100 Å). The optical auxiliary layer OAL may be formed as a silicon oxide (SiOₓ)-based inorganic film, but some embodiments of the present disclosure are not limited thereto.

Each of the light emitting elements LE may include the first electrode AND, the light emitting stack IL, and the second electrode CAT.

The first electrode AND may be located on the optical auxiliary layer OAL. For example, the first electrode AND may be located on an upper surface of the optical auxiliary layer OAL, side surfaces of the optical auxiliary layer OAL, side surfaces of the connection electrode ANC, and an upper surface of the ninth insulating layer INS9. The first electrode AND may be in contact (or in direct contact) with each of the upper surface of the optical auxiliary layer OAL, the side surfaces of the optical auxiliary layer OAL, the side surfaces of the connection electrode ANC, and the upper surface of the ninth insulating layer INS9. As a side surface of the first electrode AND and the side surface of the connection electrode ANC are in contact with each other, the first electrode AND and the connection electrode ANC may be electrically connected to each other. The optical auxiliary layer OAL may be located between the first electrode AND and the reflective layer RL. For example, the optical auxiliary layer OAL may be located between the side surface of the first electrode AND and the side surface of the reflective layer RL. Accordingly, direct contact between the first electrode AND and the reflective layer RL may be prevented or reduced.

A thickness of the first electrode AND on the side surface of the optical auxiliary layer OAL may be different from a thickness of the first electrode AND on the upper surface of the optical auxiliary layer OAL. For example, the thickness of the first electrode AND on the side surface of the optical auxiliary layer OAL may be smaller than the thickness of the first electrode AND on the upper surface of the optical auxiliary layer OAL. Specifically, the thickness of the first electrode AND overlapping the side surface of the reflective layer RL may be smaller than the thickness of the first electrode AND overlapping the upper surface of the reflective layer RL.

The first electrode AND of each of the light emitting elements LE may be connected to the drain region DA or the source region SA of the pixel transistor PTR through the connection electrode ANC, the first to ninth via electrodes VA1 to VA9, the first to eighth conductive layers ML1 to ML8, and the contact terminal CTE.

The first electrode AND of each of the light emitting elements LE may be made of any one of copper (Cu), aluminum (Al), tungsten (W), molybdenum (Mo), chromium (Cr), gold (Au), titanium (Ti), nickel (Ni), and neodymium (Nd), or alloys thereof.

The capping layers PDL may partition the first emission areas EA1, the second emission areas EA2, and the third emission areas EA3. The capping layer PDL may be located on a partial area of the first electrode AND of each of the light emitting elements LE. The capping layer PDL may cover an edge of the first electrode AND of each of the light emitting elements LE. The capping layer PDL may be in contact (or in direct in contact) with the first electrode AND. The capping layer PDL may be located on the first electrode AND. For example, the capping layer PDL may be located on an upper surface of the first electrode AND and side surfaces of the first electrode AND. The first capping layer PDL1 may be made of a material including silicon nitride (SiNₓ). The capping layer PDL may be made of a material that is different from a material of the planarization layer PNS (to be described later) to function as an etch stop film defining a thickness (or a height) of the planarization layer PNS when the planarization layer PNS is removed by chemical mechanical polishing (CMP).

The first emission area EA1 may be defined as an area where the first electrode AND, the light emitting stack IL, and the second electrode CAT are sequentially stacked in the first sub-pixel area SP1 to emit light. The second emission area EA2 may be defined as an area where the first electrode AND, the light emitting stack IL, and the second electrode CAT are sequentially stacked in the second sub-pixel area SP2 to emit light. The third emission area EA3 may be defined as an area where the first electrode AND, the light emitting stack IL, and the second electrode CAT are sequentially stacked in the third sub-pixel area SP3 to emit light.

The planarization layer PNS may be located between the first electrodes AND of the sub-pixel areas SP1, SP2, and SP3 in order to remove a step between the sub-pixel areas SP1, SP2, and SP3. For example, the planarization layer PNS may be located between the capping layers PDL (of each of the light emitting elements LE). The planarization layer PNS may be made of a material including silicon oxide (SiOₓ).

The separators SPR may be located on the capping layers PDL and the planarization layer PNS. In the plan view, as illustrated in FIGS. 8 and 9, each of the separators SPR may have a closed curved shape which surrounds each of the emission areas EA1, EA2, and EA3. Each of the separators SPR may be located on the capping layer PDL and the planarization layer PNS so as to surround each of the emission areas EA1, EA2, and EA3. The separator SPR may be a structure for cutting the light emitting stack IL. To this end, according to some embodiments, the separator SPR may include a first bank BK1, a second bank BK2, and a third bank BK3 that have different areas.

The first bank BK1 may be located on the capping layer PDL and the planarization layer PNS. The first bank BK1 may be made of the same material as the planarization layer PNS. For example, the first bank BK1 may be made of a material including silicon oxide (SiOₓ). In this case, the first bank BK1 and the planarization layer PNS may be formed integrally with each other without an interface.

The second bank BK2 may be located on the first bank BK1. The second bank BK2 may be located on the second bank BK2 so as to overlap the first bank BK1. In this case, an area of the second bank BK2 may be smaller than an area of the first bank BK1. For example, in the plan view, the area of the second bank BK2 may be smaller than the area of the first bank BK1 so that the second bank BK2 may be surrounded by an edge of the first bank BK1. An etch rate of the second bank BK2 may be different from an etch rate of the first bank BK1. For example, the etch rate of the second bank BK2 may be greater than the etch rate of the first bank BK1. The second bank BK2 may be made of a material including silicon nitride (SiNₓ). In some embodiments, the second bank BK2 may be made of a material including metal. For example, the second bank BK2 may be made of a material including at least one of titanium (Ti), tantalum (Ta), or molybdenum (Mo).

The third bank BK3 may be located on the second bank BK2. The third bank BK3 may be located on the second bank BK2 so as to overlap the second bank BK2. In this case, an area of the third bank BK3 may be greater than the area of the second bank BK2. For example, in the plan view, the area of the third bank BK3 may be greater than the area of the second bank BK2 so that the third bank BK3 may surround an edge of the second bank BK2. Accordingly, as illustrated in FIG. 9, the third bank BK3 may include a tip TP that does not overlap the second bank BK2. The etch rate of the second bank BK2 may be different from an etch rate of the third bank BK3. For example, the etch rate of the second bank BK2 may be greater than the etch rate of the third bank BK3. The third bank BK2 may be made of a material including silicon oxide (SiOₓ).

The separator SPR including the first bank BK1, the second bank BK2, and the third bank BK3 (described above) may have a smaller width at a center portion thereof than at an upper side and a lower side thereof in cross section.

The light emitting stack IL may be located on the first electrodes AND, the capping layers PDL, and the separators SPR. For example, the light emitting stack IL may be located on the first bank BK1 and the third bank BK3 of the separator SPR. In this case, the light emitting stack IL may be cut on the separators SPR. For example, the light emitting stack IL may be cut between the first bank BK1 and the third bank BK3. In the plan view, the light emitting stack IL may be cut along the separator SPR. Accordingly, the light emitting stack IL may be divided into a portion in contact with the first electrode AND in the emission area and a portion located on an area (e.g., the third bank BK3 of the separator SPR) excluding the emission area. In other words, the light emitting stack IL may be cut along the separator SPR so as to be separated for each sub-pixel area. Accordingly, a lateral leakage current between adjacent sub-pixel areas SP1, SP2, and SP3 may be minimized. As a lateral leakage current is minimized, a color mixing phenomenon between the adjacent sub-pixel areas SP1, SP2, and SP3 may be prevented or reduced, such that image quality of the display device 10 may be relatively improved.

The light emitting stack IL may include a plurality of stack layers that are sequentially stacked along the third direction DR3. For example, the light emitting stack IL may have a three-tandem structure including a first stack layer, a second stack layer located on the first stack layer, and a third stack layer located on the second stack layer. Here, the second stack layer may be located between the first stack layer and the third stack layer. Some embodiments of the present disclosure are not limited thereto. For example, the light emitting stack IL may also have a two-tandem structure including two stack layers.

In the three-tandem structure, the first stack layer, the second stack layer, and the third stack layer of the light emitting stack IL may provide light of different colors (or wavelengths). For example, any one of the first stack layer, the second stack layer, and the third stack layer may provide light of a first color (e.g., green), another of the first stack layer, the second stack layer, and the third stack layer may provide light of a second color (e.g., red), and the other of the first stack layer, the second stack layer, and the third stack layer may provide light of a third color (e.g., blue).

The first stack layer of the light emitting stack IL may have a structure in which a first hole transporting layer, a first organic light emitting layer, and a first electron transporting layer are sequentially stacked. The second stack layer of the light emitting stack IL may have a structure in which a second hole transporting layer, a second organic light emitting layer, and a second electron transporting layer are sequentially stacked. The third stack layer of the light emitting stack IL may have a structure in which a third hole transporting layer, a third organic light emitting layer, and a third electron transporting layer are sequentially stacked. Here, the first organic light emitting layer, the second organic light emitting layer, and the third organic light emitting layer may provide lights of different colors (or wavelengths). For example, any one of the first organic light emitting layer, the second organic light emitting layer, and the third organic light emitting layer may provide light of a first color (e.g., green), another of the first organic light emitting layer, the second organic light emitting layer, and the third organic light emitting layer may provide light of a second color (e.g., red), and the other of the first organic light emitting layer, the second organic light emitting layer, and the third organic light emitting layer may provide light of a third color (e.g., blue).

A first charge generation layer for supplying charges to the second stack layer and supplying electrons to the first stack layer may be located between the first stack layer and the second stack layer. The first charge generation layer may include an n-type charge generation layer supplying electrons to the first stack layer and a p-type charge generation layer supplying holes (e.g., positive charge carriers) to the second stack layer. The n-type charge generation layer may include a dopant of a metal material.

A second charge generation layer for supplying charges to the third stack layer and supplying electrons to the second stack layer may be located between the second stack layer and the third stack layer. The second charge generation layer may include an n-type charge generation layer supplying electrons to the second stack layer and a p-type charge generation layer supplying holes to the third stack layer.

The first stack layer of the light emitting stack IL may be located on the first electrodes AND, the capping layers PDL, and the separators SPR. The first stack layer of the light emitting stack IL may be disconnected between the sub-pixel areas SP1, SP2, and SP3 neighboring to each other by the separator SPR described above. The second stack layer of the light emitting stack IL may be located on the first stack layer. The second stack layer may be disconnected between the sub-pixel areas SP1, SP2, and SP3 neighboring to each other by the separator SPR described above. The third stack layer of the light emitting stack IL may be located on the second stack layer. The third stack layer of the light emitting stack IL may not be disconnected by the separator SPR, and may cover the second stack layer.

In the three-tandem structure, the separator SPR may be a structure for disconnecting the first charge generation layer and the second charge generation layer of the display element layer EML between the sub-pixel areas SP1, SP2, and SP3 neighboring to each other. In addition, in the two-tandem structure, the separator SPR may be a structure for disconnecting a charge generation layer located between a lower stack layer and an upper stack layer.

The second electrode CAT may be located on the light emitting stack IL. For example, the second electrode CAT may be located on the third stack layer of the light emitting stack IL. The second electrode CAT may not be disconnected by the separator SPR, and may be located on the third stack layer of the light emitting stack IL. The second electrode CAT may be made of a semi-transmissive conductive material such as magnesium (Mg), silver (Ag), or an alloy of magnesium (Mg) and silver (Ag). In this case, light emission efficiency of each of the first to third sub-pixel areas SP1, SP2, and SP3 may be increased by a microcavity.

The encapsulation layer TFE may be located on the display element layer EML. The encapsulation layer TFE may include at least one inorganic film TFE1 or TFE2 in order to prevent or reduce contaminants such as oxygen or moisture permeating into the display element layer EML. For example, the encapsulation layer TFE may include a first encapsulation inorganic film TFE1, an encapsulation organic film TFE2, and a second encapsulation inorganic film TFE3.

The first encapsulation inorganic film TFE1 may be located on the second electrode CAT. The first encapsulation inorganic film TFE1 may be formed as multiple films in which one or more inorganic films of a silicon nitride (SiNₓ) film, a silicon oxynitride (SiON) film, and a silicon oxide (SiOₓ) film are alternately stacked. The first encapsulation inorganic film TFE1 may be formed by a chemical vapor deposition (CVD) process.

The encapsulation organic film TFE2 may be made of a monomer. In some embodiments, the encapsulation organic film TFE2 may be an organic film made of an acrylic resin, an epoxy resin, a phenolic resin, a polyamide resin, a polyimide resin, or the like.

The second encapsulation inorganic film TFE3 may be located on the encapsulation organic film TFE2. The second encapsulation inorganic film TFE3 may be formed as multiple films in which one or more inorganic films of a silicon nitride (SiNₓ) film, a silicon oxynitride (SiON) film, and a silicon oxide (SiOₓ) film are alternately stacked. The second encapsulation inorganic film TFE3 may be formed by a chemical vapor deposition (CVD) process.

An organic film APL may be a layer for increasing interfacial adhesive strength between the encapsulation layer TFE and the optical layer OPL. The organic film APL may be an organic film made of an acrylic resin, an epoxy resin, a phenolic resin, a polyamide resin, a polyimide resin, or the like.

The optical layer OPL may include a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on the organic film APL.

The first color filter CF1 may overlap the first emission area EA1 of the first sub-pixel area SP1. The first color filter CF1 may transmit first light (e.g., light of a red wavelength band). Therefore, the first color filter CF1 may transmit the first light among light emitted from the light emitting stack IL of the first emission area EA1.

The second color filter CF2 may overlap the second emission area EA2 of the second sub-pixel area SP2. The second color filter CF2 may transmit second light (e.g., light of a green wavelength band). Therefore, the second color filter CF2 may transmit the second light among light emitted from the light emitting stack IL of the second emission area EA2.

The third color filter CF3 may overlap the third emission area EA3 of the third sub-pixel area SP3. The third color filter CF3 may transmit third light (e.g., light of a blue wavelength band). Therefore, the third color filter CF3 may transmit the third light among light emitted from the light emitting stack IL of the third emission area EA3.

Each of the plurality of lenses LNS may be located on each of the first color filter CF1, the second color filter CF2, and the third color filter CF3. Each of the plurality of lenses LNS may be a structure for increasing a ratio of light directed to a front surface of the display device 10. It is illustrated that each of the plurality of lenses LNS has a cross-sectional shape convex in an upward direction, but some embodiments of the present disclosure are not limited thereto.

The filling layer FIL may be located on the plurality of lenses LNS. The filling layer FIL may have a selected refractive index so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, or the like.

The cover layer CVL may be located on the filling layer FIL. The cover layer CVL may be a glass substrate or a polymer resin such as a resin. When the cover layer CVL is the glass substrate, the cover layer CVL may be attached onto the filling layer FIL. In this case, the filling layer FIL may serve to adhere the cover layer CVL. When the cover layer CVL is the glass substrate, the cover layer CVL may serve as an encapsulation substrate. When the cover layer CVL is the polymer resin such as the resin, the cover layer CVL may be directly applied onto the filling layer FIL.

The polarizing plate POL may be located on one surface of the cover layer CVL. The polarizing plate POL may be a structure for preventing or reducing deterioration in visibility due to external light reflection. The polarizing plate POL may include a linear polarizing plate and a phase retardation film. For example, the phase retardation film may be a λ/4 plate (quarter-wave plate), but some embodiments of the present disclosure are not limited thereto. However, when the deterioration in visibility due to the external light reflection is sufficiently improved by the first to third color filters CF1, CF2, and CF3, the polarizing plate POL may be omitted.

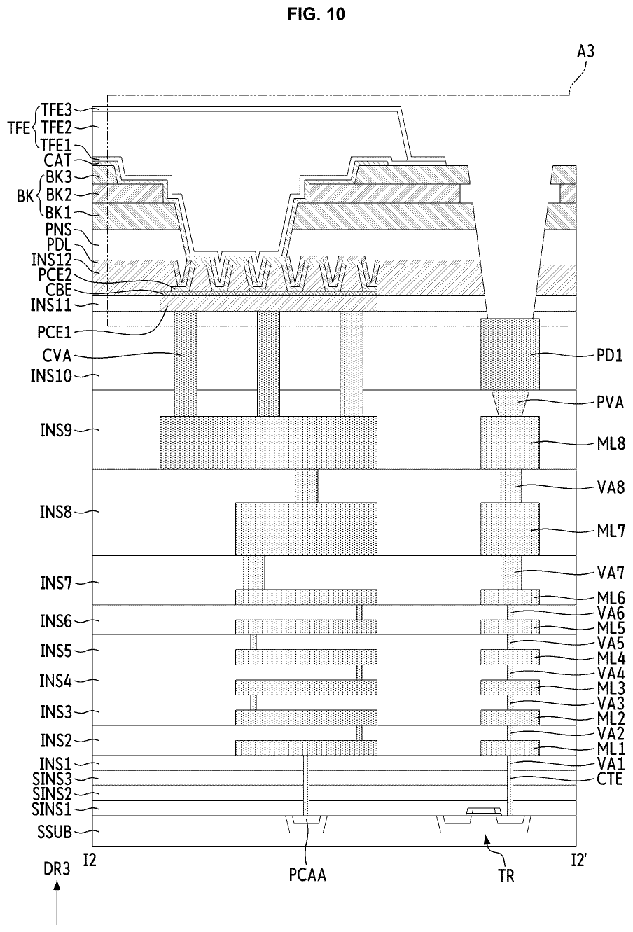

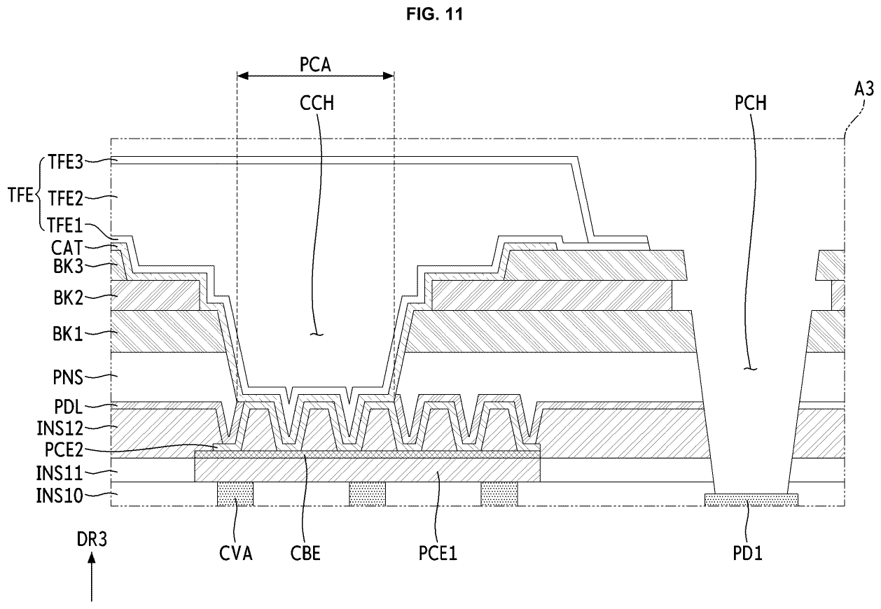

FIG. 10 is a cross-sectional view of an example of the display panel 100 taken along the line I2-I2′ of FIG. 4, and FIG. 11 is a cross-sectional view illustrating further details of the area A3 of FIG. 10.

FIGS. 10 and 11 illustrate a power connection unit PCA and a first pad PD1 located in the non-display area NDA.

The power connection unit PCA may include a power connection area PCAA of the semiconductor substrate SSUB, a first power connection electrode PCE1, and a second power connection electrode PCE2.

The first driving voltage VSS may be applied to the power connection area PCAA of the semiconductor substrate SSUB.

The first power connection electrode PCE1 may be located in a hole of an eleventh insulating layer INS11 on a tenth insulating layer INS10. The first power connection electrode PCE1 may be connected to the power connection area PCAA of the semiconductor substrate SSUB through the first to eighth conductive layers ML1 to ML8, the first to eighth via electrodes VA1 to VA8, and a power via electrode CVA. The first power connection electrode PCE1 may be made of the same material as the reflective layer RL.

A power buffer layer CBE may be located on the first power connection electrode PCE1. The power buffer layer CBE may be made of the same material as the buffer layer BE.

A twelfth insulating layer INS12 may be located on the power buffer layer CBE. The twelfth insulating layer INS12 may be made of the same material as the optical auxiliary layer OAL described above.

The second power connection electrode PCE2 may be located on the twelfth insulating layer INS12. The second power connection electrode PCE2 may be connected to the power buffer layer CBE through a plurality of contact holes penetrating through the twelfth insulating layer INS12. For example, the second power connection electrode PCE2 may be connected to the first power connection electrode PCE1 through the power buffer layer CBE. The second power connection electrode PCE2 may include the same (or substantially the same) material as the first electrode AND.

The second electrode CAT may be connected to the second power connection electrode PCE2 through a power contact hole CCH penetrating through the third bank BK3, the second bank BK2, the first bank BK1, the planarization layer PNS, and the capping layer PDL.

The tenth insulating layer INS10 may be located between the ninth insulating layer INS9 and the eleventh insulating layer INS11. A tenth via electrode VA10 may be located in the tenth insulating layer INS10.

The first pad PD1 may be located on the ninth insulating layer INS9. The first pad PD1 may be connected to a transistor TR on the semiconductor substrate SSUB through the first to eighth conductive layers ML1 to ML8, the first to eighth via electrodes VA1 to VA8, and a pad via electrode PVA. The first pad PD1 may be made of the same material as the reflective layer RL. For example, the first pad PD1 may be made of a material including aluminum (Al). A thickness of the first pad PD1 may be 12,000 Å (or approximately 12,000 Å).

The first pad PD1 may be exposed to the outside through a pad contact hole PCH penetrating through the third bank BK3, the second bank BK2, the first bank BK1, the planarization layer PNS, the capping layer PDL, the twelfth insulating layer INS12, the eleventh insulating layer INS11, and the tenth insulating layer INS10. The first pad PD1 may be electrically connected to a pad or a bump of a circuit board 300 through the pad contact hole PCH.

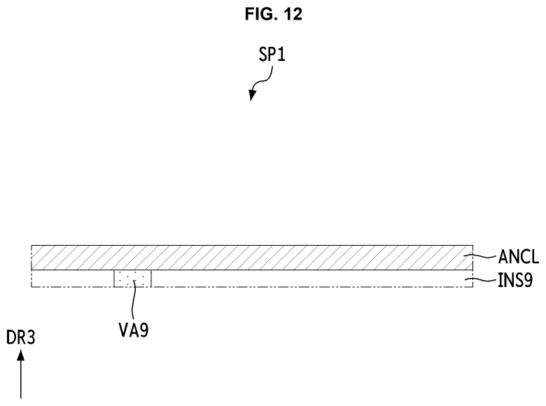

FIGS. 12 to 31 are views illustrating processes of a method for fabricating a display device according to some embodiments. For example, FIGS. 12 to 31 may be cross-sectional views for describing processes of a method for fabricating the display device 10 (including the display panel 100) of FIG. 9.

First, as illustrated in FIG. 12, the ninth insulating layer INS9 may be formed on the semiconductor substrate SSUB, and the ninth via electrode VA9 may be formed in a via hole of the ninth insulating layer INS9. Thereafter, a connection electrode layer ANCL may be formed on the ninth insulating layer INS9 so as to be in contact with the ninth via electrode VA9. For example, the connection electrode layer ANCL may be formed on an entire surface of the semiconductor substrate SSUB including the ninth insulating layer INS9 and the ninth via electrode VA9 so as to cover the ninth insulating layer INS9 and the ninth via electrode VA9.

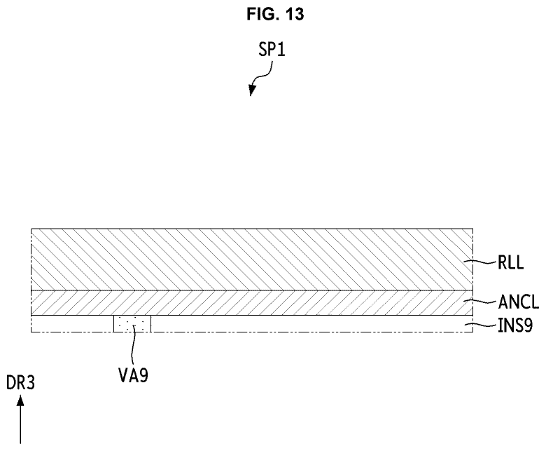

Thereafter, as illustrated in FIG. 13, a preliminary reflective layer RLL may be formed on the connection electrode layer ANCL. For example, the preliminary reflective layer RLL may be formed on the entire surface of the semiconductor substrate SSUB including the connection electrode layer ANCL so as to cover the connection electrode layer ANCL.

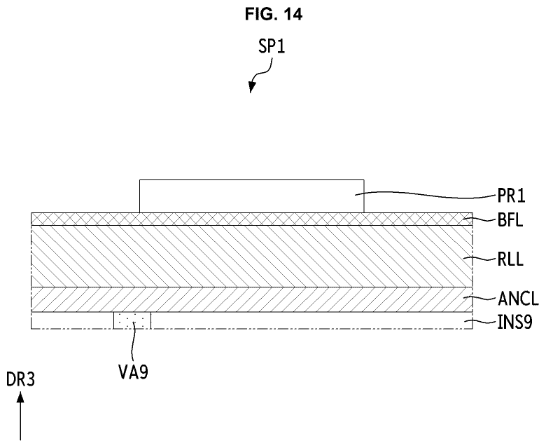

Next, as illustrated in FIG. 14, a preliminary buffer layer BFL may be formed on the preliminary reflective layer RLL. For example, the preliminary buffer layer BFL may be formed on the entire surface of the semiconductor substrate SSUB including the preliminary reflective layer RLL so as to cover the preliminary reflective layer RLL. Thereafter, a first photoresist pattern PR1 may be formed on the preliminary buffer layer BFL. For example, the first photoresist pattern PR1 may be formed on the preliminary buffer layer BFL so as to overlap each of the emission areas EA1, EA2, and EA3.

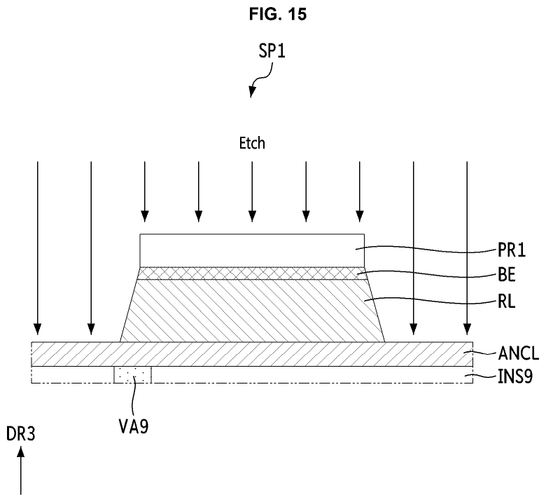

Subsequently, as illustrated in FIG. 15, the preliminary buffer layer BFL and the preliminary reflective layer RLL may be patterned using the first photoresist pattern PR1 as a mask. For example, by etching and patterning the preliminary buffer layer BFL and the preliminary reflective layer RLL together through an etching (e.g., dry etching) process that utilizes the first photoresist pattern PR1 as the mask, the reflective layer RL and the buffer layer BE may be formed for each of the sub-pixel areas SP1, SP2, and SP3.

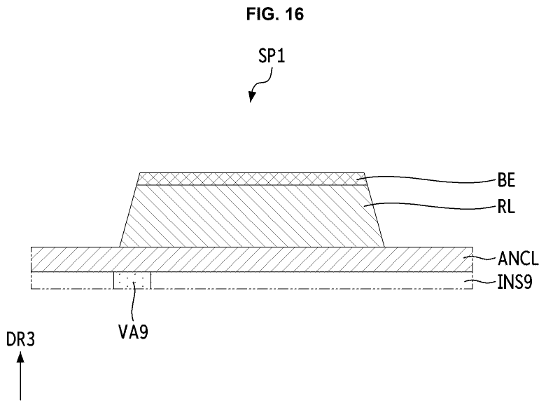

Thereafter, as illustrated in FIG. 16, the first photoresist pattern PR1 may be removed. The first photoresist pattern PR1 may be removed by an ashing process. After the first photoresist pattern PR1 is removed, a cleaning process may be performed on the semiconductor substrate SSUB.

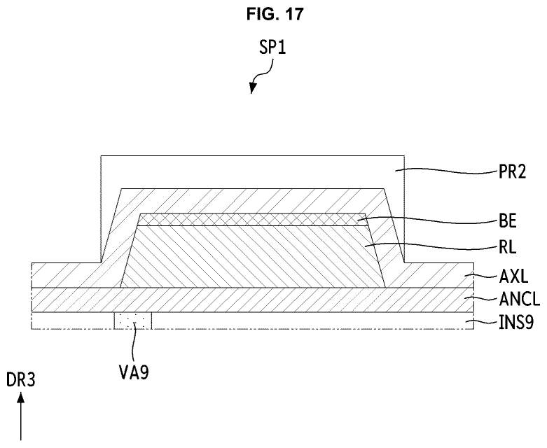

Next, as illustrated in FIG. 17, an auxiliary layer AXL may be formed on the buffer layer BE. For example, the auxiliary layer AXL may be formed on the entire surface of the semiconductor substrate SSUB including the buffer layer BE and the reflective layer RL so as to cover an upper surface of the buffer layer BE and side surfaces of the reflective layer RL. The exposed side surfaces of the reflective layer RL may be covered and protected by the auxiliary layer AXL. Thereafter, a second photoresist pattern PR2 may be formed on the auxiliary layer AXL. For example, the second photoresist pattern PR2 may be formed on the auxiliary layer AXL so as to overlap each of the emission areas EA1, EA2, and EA3 or each of the reflective layers RL.

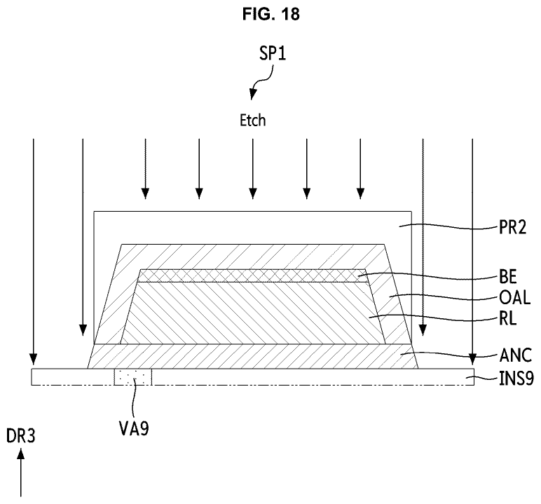

Subsequently, as illustrated in FIG. 18, the auxiliary layer AXL and the connection electrode layer ANCL may be patterned using the second photoresist pattern PR2 as a mask. For example, by etching and patterning the auxiliary layer AXL and the connection electrode layer ANCL together through an etching (e.g., dry etching) process that utilizes the second photoresist pattern PR2 as the mask, the connection electrode ANC and the optical auxiliary layer OAL may be formed for each of the sub-pixel areas SP1, SP2, and SP3. The upper surface and the side surfaces of the reflective layer RL may be covered by the optical auxiliary layer OAL.

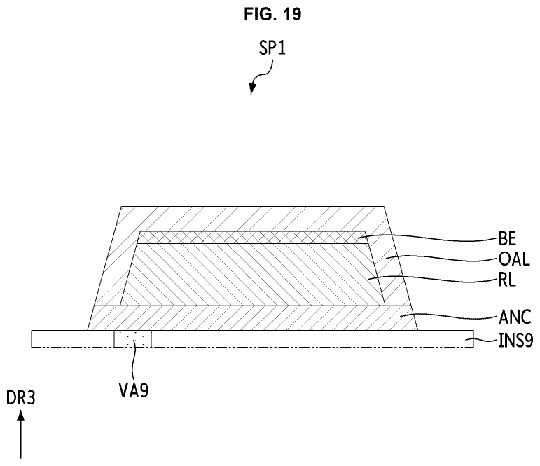

Thereafter, as illustrated in FIG. 19, the second photoresist pattern PR2 may be removed. The second photoresist pattern PR2 may be removed by an ashing process. After the second photoresist pattern PR2 is removed, a cleaning process may be performed on the semiconductor substrate SSUB.

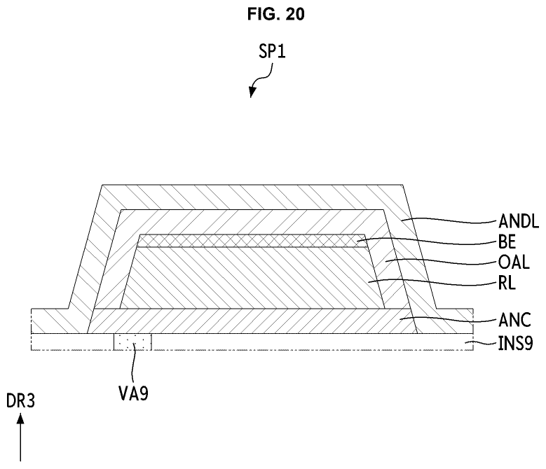

Next, as illustrated in FIG. 20, a first electrode layer ANDL may be formed on the optical auxiliary layer OAL. For example, the first electrode layer ANDL may be formed on the entire surface of the semiconductor substrate SSUB including the optical auxiliary layer OAL and the connection electrode ANC so as to cover an upper surface of the optical auxiliary layer OAL, side surfaces of the optical auxiliary layer OAL, and side surface of the connection electrode ANC.

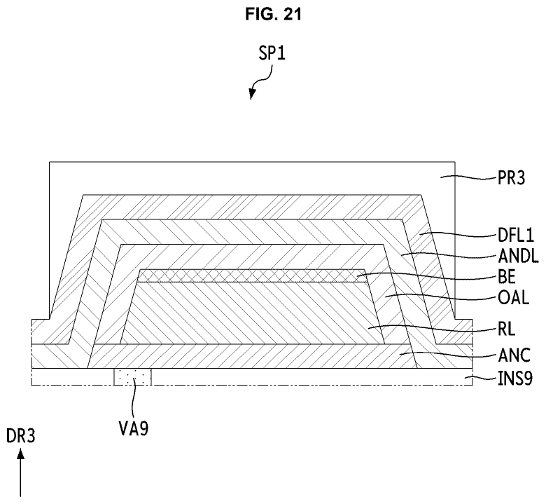

Subsequently, as illustrated in FIG. 21, a first preliminary capping layer DFL1 may be formed on the first electrode layer ANDL. For example, the first preliminary capping layer DFL1 may be formed on the entire surface of the semiconductor substrate SSUB including the first electrode layer ANDL so as to cover the first electrode layer ANDL. Thereafter, a third photoresist pattern PR3 may be formed on the first preliminary capping layer DFL1. For example, the third photoresist pattern PR3 may be formed on the first preliminary capping layer DFL1 so as to overlap each of the emission areas EA1, EA2, and EA3.

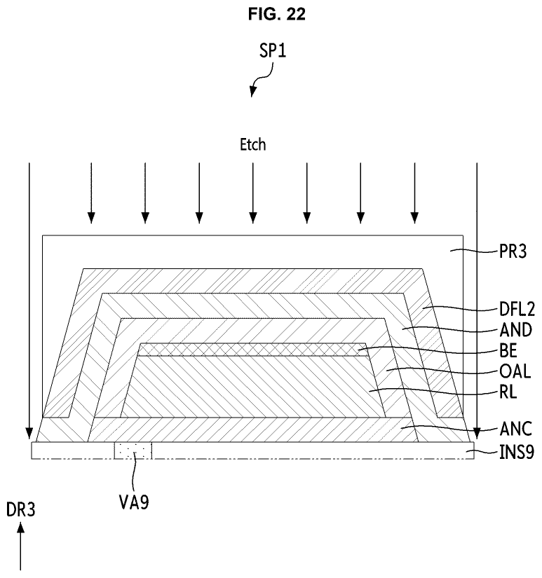

Subsequently, as illustrated in FIG. 22, the first preliminary capping layer DFL1 and the first electrode layer ANDL may be patterned using the third photoresist pattern PR3 as a mask. For example, by etching and patterning the first preliminary capping layer DFL1 and the first electrode layer ANDL together using an etching (e.g., dry etching) process that utilizes the third photoresist pattern PR3 as the mask, the first electrode AND and a second preliminary capping layer DFL2 may be formed for each of the sub-pixel areas SP1, SP2, and SP3.

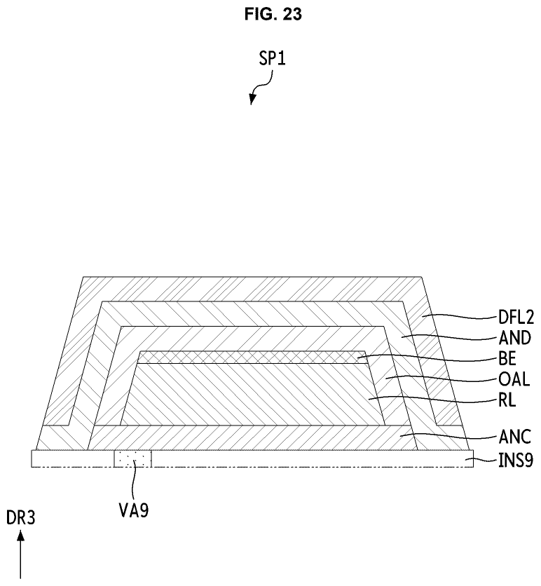

Thereafter, as illustrated in FIG. 23, the third photoresist pattern PR3 may be removed. The third photoresist pattern PR3 may be removed by an ashing process. After the third photoresist pattern PR3 is removed, a cleaning process may be performed on the semiconductor substrate SSUB. For example, a polymer may remain as a reaction byproduct on a sidewall of a patterned metal or on the patterned metal after the dry etching process, and a cleaning process of removing such a polymer using a stripper including a solvent may be performed. Here, hydrogen fluoride (e.g., diluted HF) may be used as the stripper.

When the first electrode AND is made of a material including ITO, a silver (Ag) component of the reflective layer RL may protrude onto the first electrode AND through a pin hole of the first electrode AND. For example, a portion of the reflective layer RL may be swelled due to heat during a curing process (e.g., a heat treatment process) for alleviating a defect that may occur in a subsequent process, and the swelled portion of the reflective layer RL may be exposed to the outside through the pin hole of the first electrode AND. In this case, the portion of the reflective layer RL exposed to the outside through the pin hole may be exposed to hydrogen fluoride used in the above-described cleaning process (e.g., the cleaning process performed after the third photoresist pattern PR3 is removed). In this case, hydrogen fluoride may permeate into the reflective layer RL using the exposed portion of the reflective layer RL as a permeation path. In such a case, the reflective layer RL may be damaged. When the reflective layer RL is damaged due to the exposure to hydrogen fluoride, at least a portion of the reflective layer RL may be lost. In such a case, light efficiency may be relatively reduced in the emission area where the reflective layer RL is lost, such that image quality of the display device 10 may be deteriorated.

However, according to some embodiments, the optical auxiliary layer OAL may be located between the reflective layer RL and the first electrode AND, and thus, the swelled portion of the reflective layer RL may not pass through the pin hole of the first electrode AND. Accordingly, hydrogen fluoride used during the cleaning process after the first electrode AND is formed may not permeate into the reflective layer RL. Therefore, according to some embodiments, even during the cleaning process, the damage to the reflective layer RL may be prevented or reduce by the optical auxiliary layer OAL.

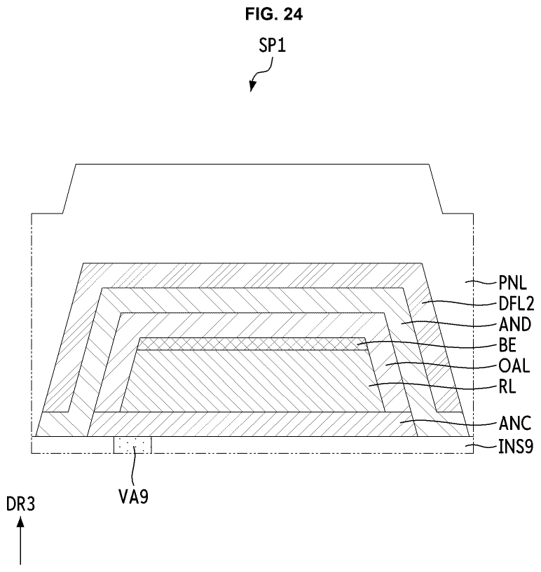

Next, as illustrated in FIG. 24, a preliminary planarization layer PNL may be formed on the ninth insulating layer INS9 and the patterned second preliminary capping layer DFL2. For example, the preliminary planarization layer PNL may be formed on the entire surface of the semiconductor substrate SSUB including the ninth insulating layer INS9 and the second preliminary capping layer DFL2 so as to cover the ninth insulating layer INS9 and the second preliminary capping layer DFL2. In this case, the preliminary planarization layer PNL may have a bend along a step of an underlying structure. In this case, the lowest portion of the preliminary planarization layer PNL may be higher than the highest portion of the second preliminary capping layer DFL2.

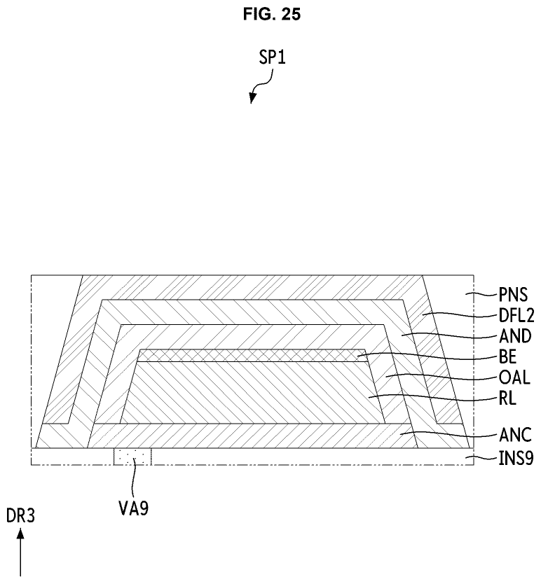

Thereafter, as illustrated in FIG. 25, the planarization layer PNS may be formed by removing a portion of the preliminary planarization layer PNL above the second preliminary capping layer DFL2. For example, the preliminary planarization layer PNL may be removed and planarized through chemical mechanical polishing. In other words, the planarization layer PNS may be formed by removing the preliminary planarization layer PNL until the highest portion of the second preliminary capping layer DFL2 is exposed. An upper surface of the planarization layer PNS may be located at the same (or substantially the same) height as the highest portion of the second preliminary capping layer DFL2.

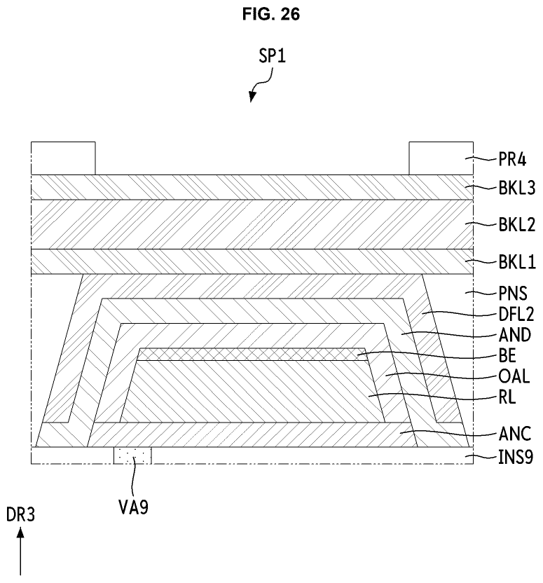

Next, as illustrated in FIG. 26, a first bank layer BKL1 may be formed on the planarization layer PNS and the exposed second preliminary capping layer DFL2, a second bank layer BKL2 may be formed on the first bank layer BKL1, and a third bank layer BKL3 may be formed on the second bank layer BKL2. Subsequently, a fourth photoresist pattern PR4 may be formed on the third bank layer BKL3. For example, the fourth photoresist pattern PR4 may be formed on the third bank layer BKL3 so as not to overlap each of the emission areas EA1, EA2, and EA3.

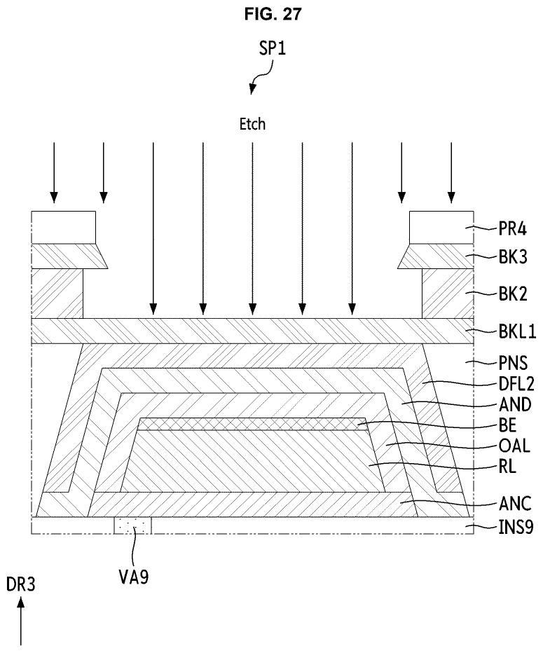

Next, as illustrated in FIG. 27, the third bank layer BKL3 and the second bank layer BKL2 may be patterned using the fourth photoresist pattern PR4 as a mask. For example, by etching and patterning the third bank layer BKL3 and the second bank layer BKL2 through an etching process that utilizes the fourth photoresist pattern PR4 as the mask, the third bank BK3 and the second bank BK2 may be formed. In this case, the second bank layer BKL2 located below the third bank layer BKL3 may have a higher etch rate than the third bank layer BKL3, and thus, the second bank layer BKL2 may be etched faster than the third bank layer BKL3 during the etching process. Accordingly, after the etching (e.g., over etching) is completed, an area of the second bank BK2 may be smaller than an area of the third bank BK3. Accordingly, a structure including the second bank BK2 and the third bank BK3 may have an undercut shape. As described above, by patterning the third bank layer BKL3 and the second bank layer BKL2 using the fourth photoresist pattern PR4 as the mask, the first bank layer BKL1 may be exposed.

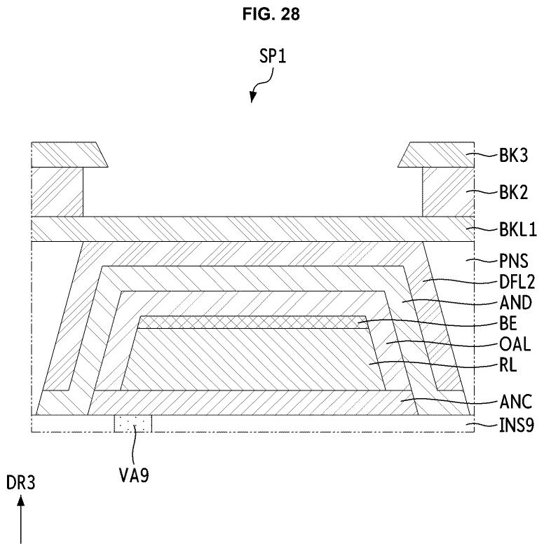

Thereafter, as illustrated in FIG. 28, the fourth photoresist pattern PR4 may be removed. The fourth photoresist pattern PR4 may be removed by an ashing process. After the fourth photoresist pattern PR4 is removed, a cleaning process may be performed on the semiconductor substrate SSUB.

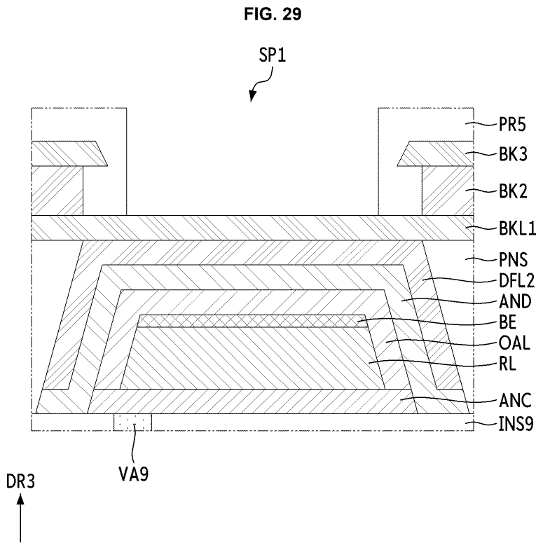

Next, as illustrated in FIG. 29, a fifth photoresist pattern PR5 may be formed on the first bank layer BKL1 and the third bank BK3. For example, the fifth photoresist pattern PR5 may be formed on the first bank layer BKL1 and the third bank BK3 so as to overlap each of the emission areas EA1, EA2, and EA3.

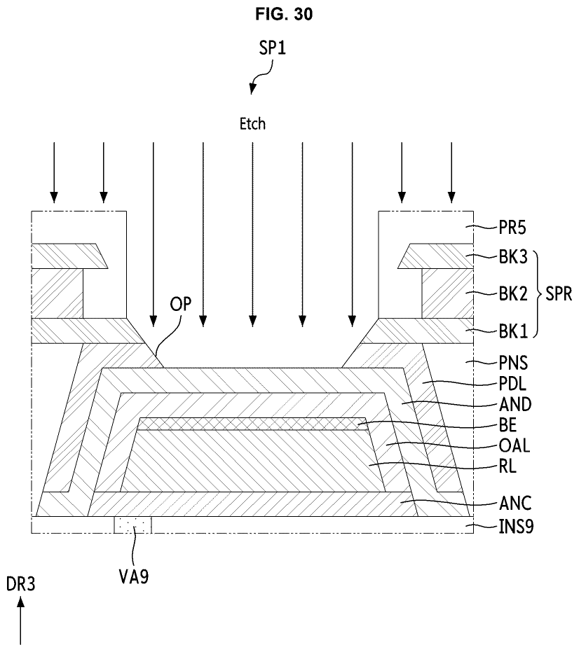

Subsequently, as illustrated in FIG. 30, the first bank layer BKL1 and the second preliminary capping layer DFL2 may be patterned using the fifth photoresist pattern PR5 as a mask. For example, by etching and patterning the first bank layer BKL1 and the second preliminary capping layer DFL2 together through an etching process that utilizes the fifth photoresist pattern PR5 as the mask, the first bank BK1 and the capping layer PDL may be formed. For example, the capping layer PDL having openings OP defining the first emission area EA1, the second emission area EA2, and the third emission area EA3 and exposing the first electrodes AND may be formed, and the separator SPR including the first to third banks BK1 to BK3 may be formed. Accordingly, the first electrodes AND may be exposed for each of the sub-pixel areas SP1, SP2, and SP3 through the first emission area EA1, the second emission area EA2, and the third emission area EA3.

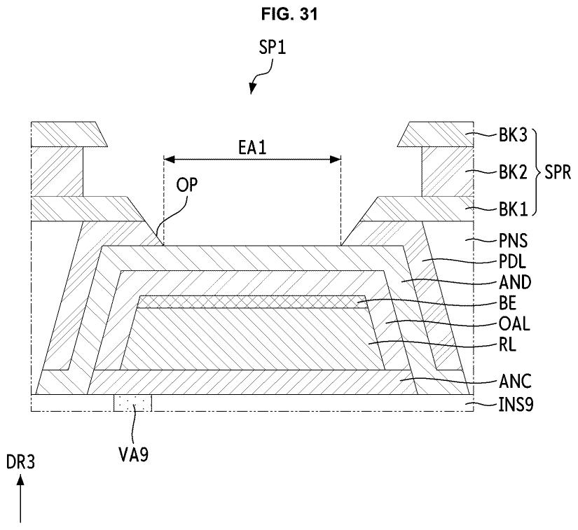

Thereafter, as illustrated in FIG. 31, the fifth photoresist pattern PR5 may be removed. The fifth photoresist pattern may be removed by an ashing process. After the fifth photoresist pattern PR5 is removed, a cleaning process may be performed on the semiconductor substrate SSUB.

Next, as illustrated in FIG. 9, the light emitting stack IL may be formed on the first electrodes AND, the capping layers PDL, and the separators SPR, the second electrode CAT may be formed on the light emitting stack IL, and the encapsulation layer TFE may be formed on the second electrode CAT. Here, the light emitting stack IL may be separated for each of the sub-pixel areas SP1, SP2, and SP3 by the separators SPR.

Through the processes illustrated in FIGS. 13 to 23 described above, the power buffer layer CBE, the first power connection electrode PCE1, the twelfth insulating layer INS12, and the second power connection electrode PCE2 may be formed in the power connection area PCAA. The power buffer layer CBE may be made of the same material as the buffer layer BE (described above), the first power connection electrode PCE1 may be made of the same material as the reflective layer RL (described above), the twelfth insulating layer INS12 may be made of the same material as the optical auxiliary layer OAL, and the second power connection electrode PCE2 may be made of the same material as the first electrode AND (described above).

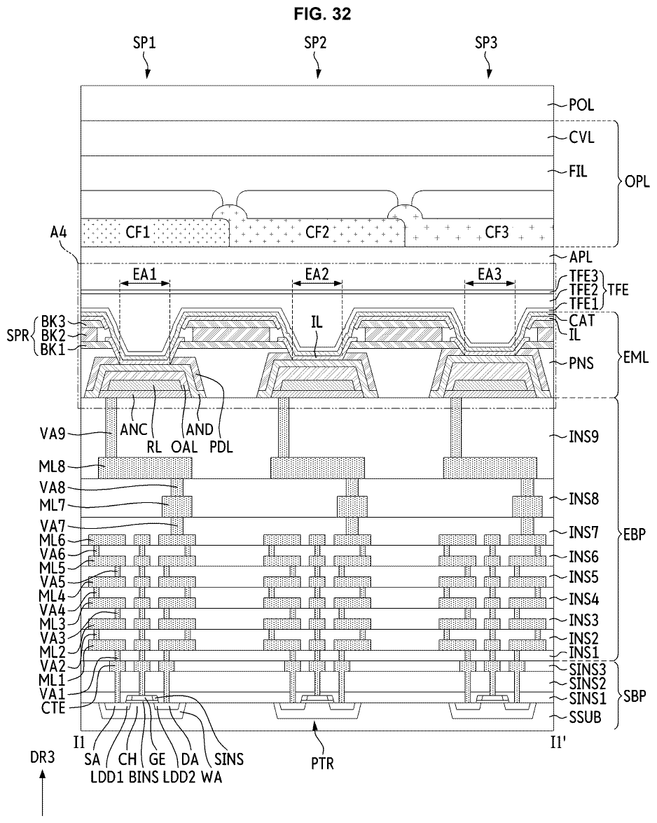

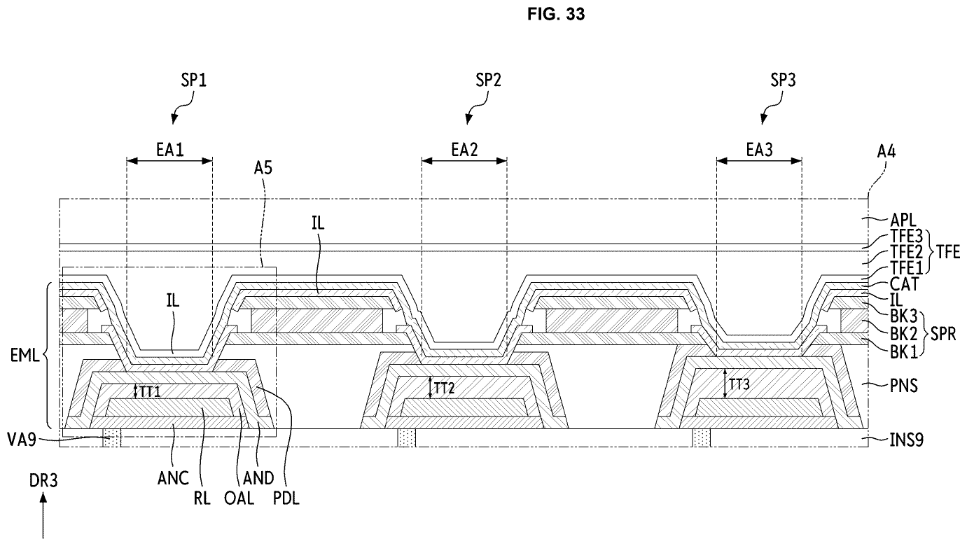

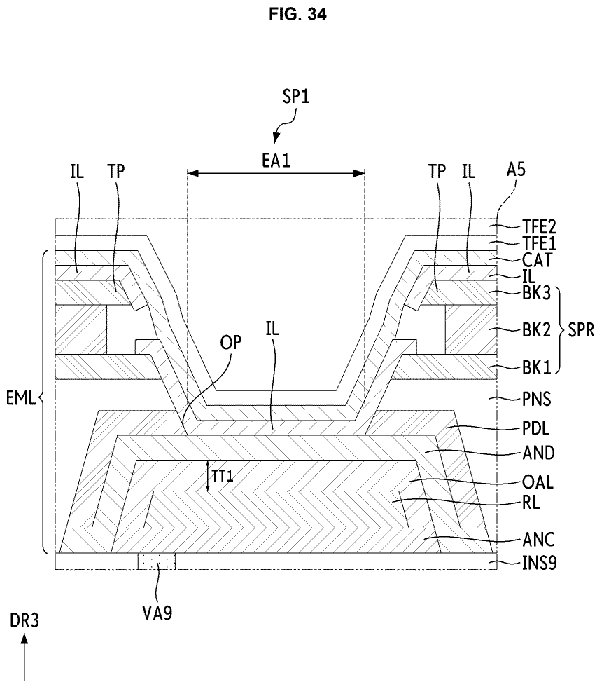

FIG. 32 is a cross-sectional view of an example of the display panel 100 taken along the line I1-I1′ of FIG. 5. FIG. 33 is a cross-sectional view illustrating further details of the area A4 of FIG. 32, and FIG. 34 is a cross-sectional view illustrating further details of the area A5 of FIG. 33.

A display device 10 (including the display panel 100) of FIGS. 32 to 34 may be different from the display device 10 described above with reference to FIGS. 7 to 9 in that it may include optical auxiliary layers OAL having different thicknesses for each of the sub-pixel areas SP1, SP2, and SP3 and may not include the buffer layers BE, and such a difference will be mainly described below.

As illustrated in FIGS. 32 to 34, the optical auxiliary layers OAL may be located on the reflective layers RL, respectively. For example, the optical auxiliary layer OAL may be located on an upper surface of the reflective layer RL and side surfaces of the reflective layer RL. The optical auxiliary layer OAL may be in contact (or in direct contact) with each of the upper surface of the reflective layer RL and the side surfaces of the reflective layer RL. In addition, the optical auxiliary layer OAL may be located on an edge of the connection electrode ANC. The optical auxiliary layer OAL may be in contact (or in direct contact) with an edge of an upper surface of the connection electrode ANC. The optical auxiliary layer OAL may surround the upper surface and the side surfaces of the reflective layer RL. In this case, the optical auxiliary layer OAL may completely surround the reflective layer RL together with the connection electrode ANC. For example, in a cross-section, the reflective layer RL may be completely surrounded by the optical auxiliary layer OAL and the connection electrode ANC. The optical auxiliary layer OAL may be formed as a silicon oxide (SiOₓ)-based inorganic film, but some embodiments of the present disclosure are not limited thereto.

The first electrode AND may be located on the optical auxiliary layer OAL. For example, the first electrode AND may be located on an upper surface of the optical auxiliary layer OAL, side surfaces of the optical auxiliary layer OAL, side surfaces of the connection electrode ANC, and an upper surface of the ninth insulating layer INS9. The first electrode AND may be in contact (or in direct contact) with each of the upper surface of the optical auxiliary layer OAL, the side surfaces of the optical auxiliary layer OAL, the side surfaces of the connection electrode ANC, and the upper surface of the ninth insulating layer INS9. As a side surface of the first electrode AND and the side surface of the connection electrode ANC are in contact with each other, the first electrode AND and the connection electrode ANC may be electrically connected to each other. The optical auxiliary layer OAL may be located between the first electrode AND and the reflective layer RL. For example, the optical auxiliary layer OAL may be located between the side surface of the first electrode AND and the side surface of the reflective layer RL. Accordingly, direct contact between the first electrode AND and the reflective layer RL may be prevented or reduced.

A thickness of the first electrode AND on the side surface of the optical auxiliary layer OAL may be different from a thickness of the first electrode AND on the upper surface of the optical auxiliary layer OAL. For example, the thickness of the first electrode AND on the side surface of the optical auxiliary layer OAL may be smaller than the thickness of the first electrode AND on the upper surface of the optical auxiliary layer OAL. Specifically, the thickness of the first electrode AND overlapping the side surface of the reflective layer RL may be smaller than the thickness of the first electrode AND overlapping the upper surface of the reflective layer RL.

The optical auxiliary layer OAL of each of the sub-pixel areas SP1, SP2, and SP3 may prevent or reduce the reflective layer RL being damaged by hydrogen fluoride used during the cleaning process as described above.

In addition, the optical auxiliary layers OAL may also serve as resonance adjusting layers increasing efficiency of light by making resonance distances of the respective sub-pixel areas SP1, SP2, and SP3 different from each other. To this end, according to some embodiments, the optical auxiliary layers OAL may have different thicknesses for each of the sub-pixel areas SP1, SP2, and SP3.

For example, a thickness TT1 of the optical auxiliary layer OAL in the first sub-pixel area SP1, a thickness TT2 of the optical auxiliary layer OAL in the second sub-pixel area SP2, and a thickness TT3 of the optical auxiliary layer OAL in the third sub-pixel area SP3 may be different from each other. For example, the thickness TT2 of the optical auxiliary layer OAL in the second sub-pixel area SP2 may be greater than the thickness TT1 of the optical auxiliary layer OAL in the first sub-pixel area SP1 and smaller than the thickness TT3 of the optical auxiliary layer OAL in the third sub-pixel area SP3.

The thickness TT1 of the optical auxiliary layer OAL in the first sub-pixel area SP1, the thickness TT2 of the optical auxiliary layer OAL in the second sub-pixel area SP2, and the thickness TT3 of the optical auxiliary layer OAL in the third sub-pixel area SP3 may be set in consideration of (e.g., based on) a main peak wavelength of the first light, a main peak wavelength of the second light, a main peak wavelength of the third light, a distance from the first stack layer of the light emitting stack IL to the reflective layer RL in the first emission area EA1, a distance from the second stack layer of the light emitting stack IL to the reflective layer RL in the second emission area EA2, and a distance from the third stack layer of the light emitting stack IL in the third emission area EA3. Accordingly, a resonance distance of the first light, a resonance distance of the second light, and a resonance distance of the third light may be set.

In some embodiments, in the display device of FIGS. 32 to 34, the buffer layer BE (described above) may be further located between the reflective layer RL and the optical auxiliary layer OAL. For example, the buffer layer BE may be located between the upper surface of the reflective layer RL and a lower surface of the optical auxiliary layer OAL.

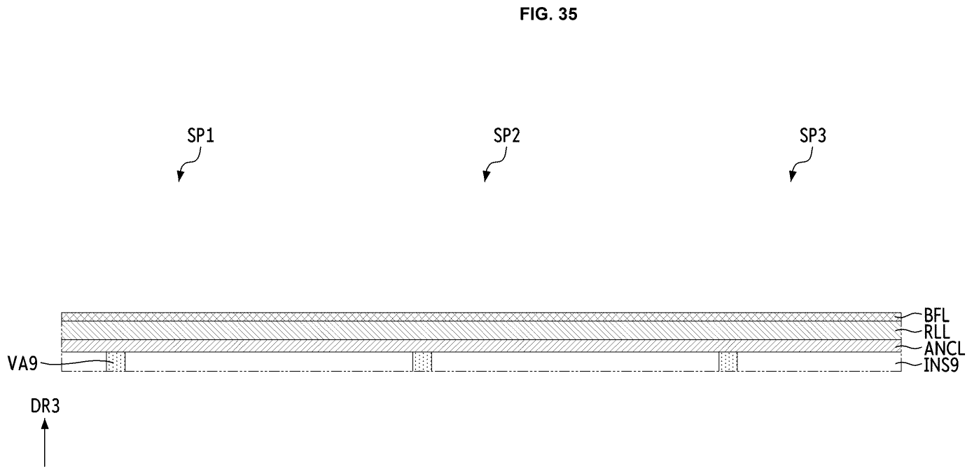

FIGS. 35 to 50 are views illustrating processes of a method for fabricating a display device according to some embodiments. For example, FIGS. 35 to 50 may be cross-sectional views for describing processes of a method for fabricating the display device 10 (including the display panel 100) described with reference to FIG. 33.

First, as illustrated in FIG. 35, the ninth insulating layer INS9 may be formed on the semiconductor substrate SSUB, and the ninth via electrode VA9 may be formed in a via hole of the ninth insulating layer INS9. Thereafter, a connection electrode layer ANCL may be formed on the ninth insulating layer INS9 so as to be in contact with the ninth via electrode VA9. For example, the connection electrode layer ANCL may be formed on an entire surface of the semiconductor substrate SSUB including the ninth insulating layer INS9 and the ninth via electrode VA9 so as to cover the ninth insulating layer INS9 and the ninth via electrode VA9. Next, a preliminary reflective layer RLL may be formed on the entire surface of the semiconductor substrate SSUB including the connection electrode layer ANCL, and a preliminary buffer layer BFL may be then formed on the entire surface of the semiconductor substrate SSUB including the preliminary reflective layer RLL. In this case, the connection electrode layer ANCL, the preliminary reflective layer RLL, and the preliminary buffer layer BFL may also be formed on the power connection area PCAA.

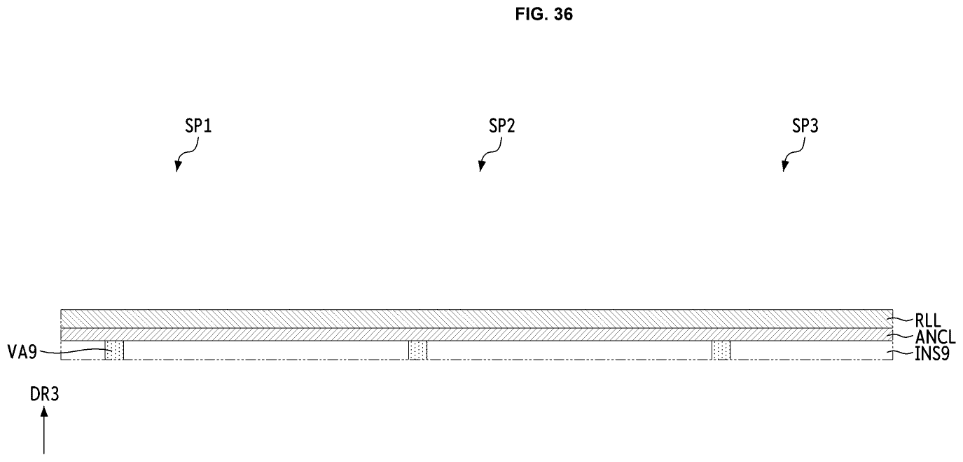

Subsequently, as illustrated in FIG. 36, by patterning the preliminary buffer layer BFL, the power buffer layer CBE may be formed on the power connection area PCAA. In other words, the preliminary buffer layer BFL on the preliminary reflective layer RLL may be removed.

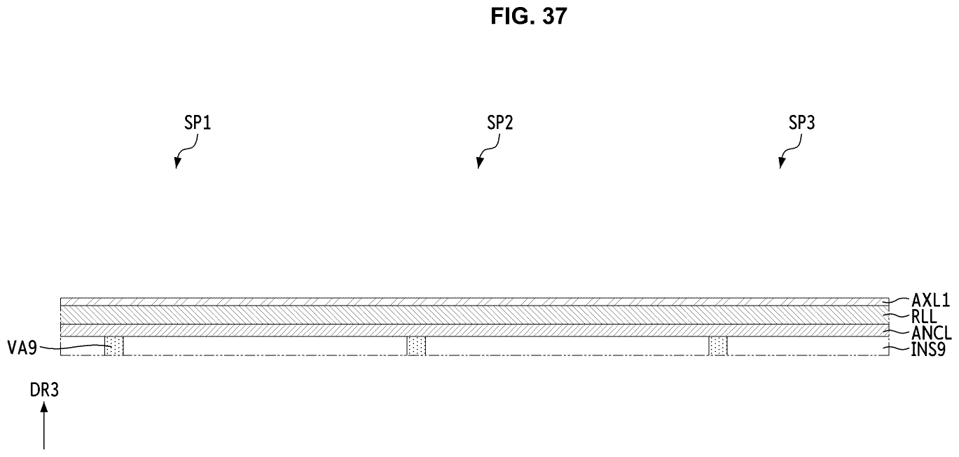

Next, as illustrated in FIG. 37, a first preliminary step layer AXL1 may be formed on the entire surface of the semiconductor substrate SSUB including the preliminary reflective layer RLL. Here, the first preliminary step layer AXL1 may be deposited on the entire surface of the semiconductor substrate SSUB by, for example, an atomic layer deposition (ALD) method.

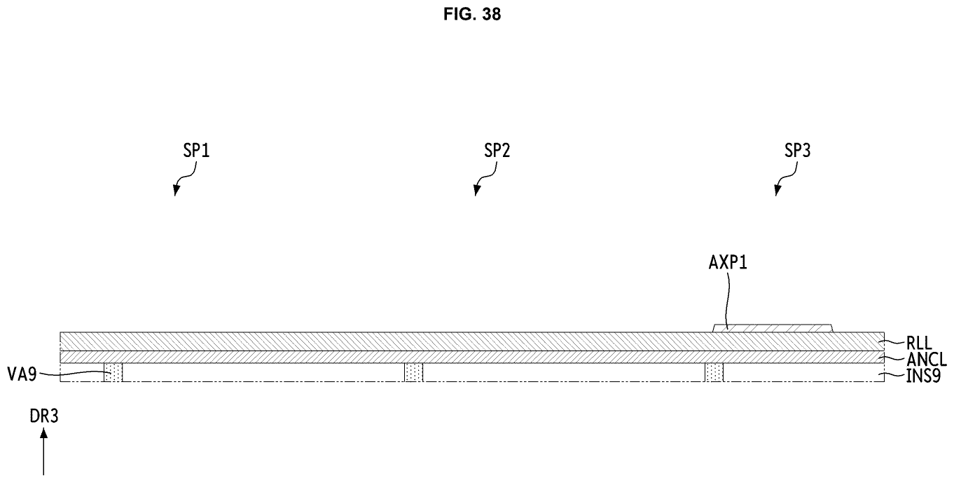

Thereafter, as illustrated in FIG. 38, a first step layer AXP1 may be formed on the preliminary reflective layer RLL of the third sub-pixel area SP3. For example, by patterning the first preliminary step layer AXL1 through a photolithography process, the first step layer AXP1 may be formed on the preliminary reflective layer RLL of the third sub-pixel area SP3.

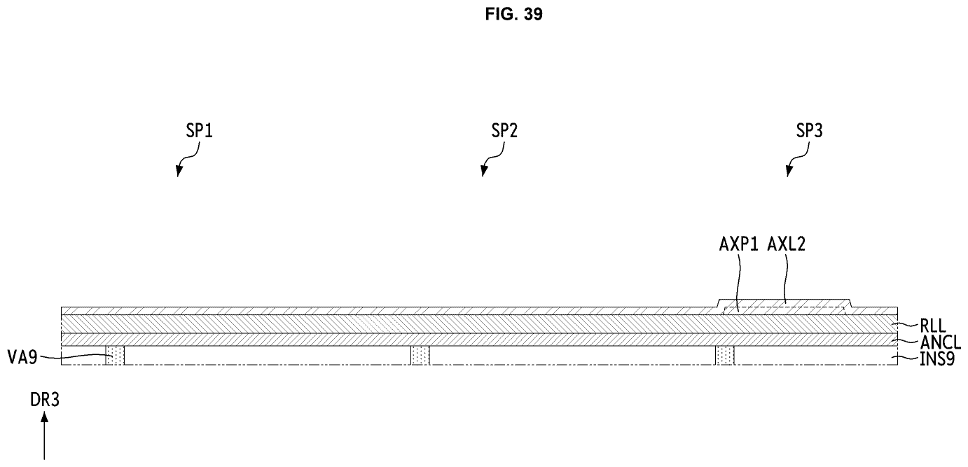

Next, as illustrated in FIG. 39, a second preliminary step layer AXL2 may be formed on the entire surface of the semiconductor substrate SSUB including the first step layer AXP1 and the preliminary reflective layer RLL. Here, the second preliminary step layer AXL2 may be deposited on the entire surface of the semiconductor substrate SSUB by, for example, an ALD method.

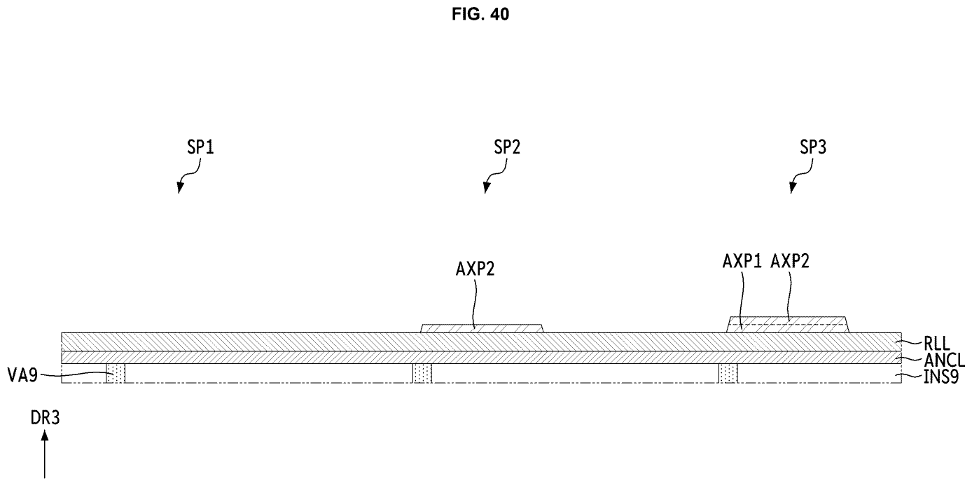

Thereafter, as illustrated in FIG. 40, second step layers AXP2 may be formed on the preliminary reflective layer RLL of the second sub-pixel area SP2 and the first step layer AXP1 of the third sub-pixel area SP3, respectively. For example, by patterning the second preliminary step layer AXL2 through a photolithography process, the second step layers AXP2 may be formed on the preliminary reflective layer RLL of the second sub-pixel area SP2 and the first step layer AXP1 of the third sub-pixel area SP3, respectively.

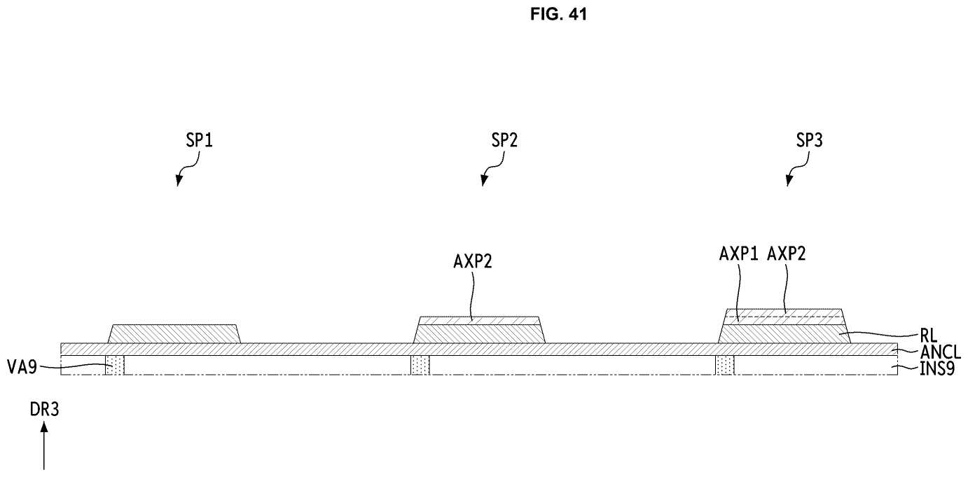

Subsequently, as illustrated in FIG. 41, by patterning the preliminary reflective layer RLL through a photolithography process, the reflective layers RL may be formed in the first sub-pixel area SP1, the second sub-pixel area SP2, and the third sub-pixel area SP3, respectively. For example, the reflective layer RL of the first sub-pixel area SP1 may be formed on the connection electrode layer ANCL of the first sub-pixel area SP1, the reflective layer RL of the second sub-pixel area SP2 may be formed between the connection electrode layer ANCL and the second step layer AXP2 of the second sub-pixel area SP2, and the reflective layer RL of the third sub-pixel area SP3 may be formed between the connection electrode layer ANCL and the first step layer AXP1 of the third sub-pixel area SP3.

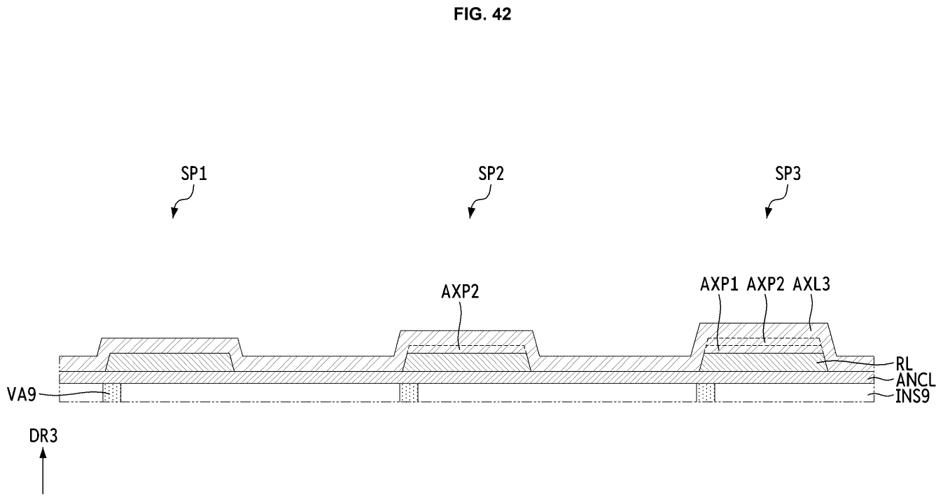

Next, as illustrated in FIG. 42, a third preliminary step layer AXL3 may be formed on the entire surface of the semiconductor substrate SSUB including the reflective layers RL and the second step layers AXP2. Here, the third preliminary step layer AXL3 may be deposited on the entire surface of the semiconductor substrate SSUB by, for example, an ALD method.

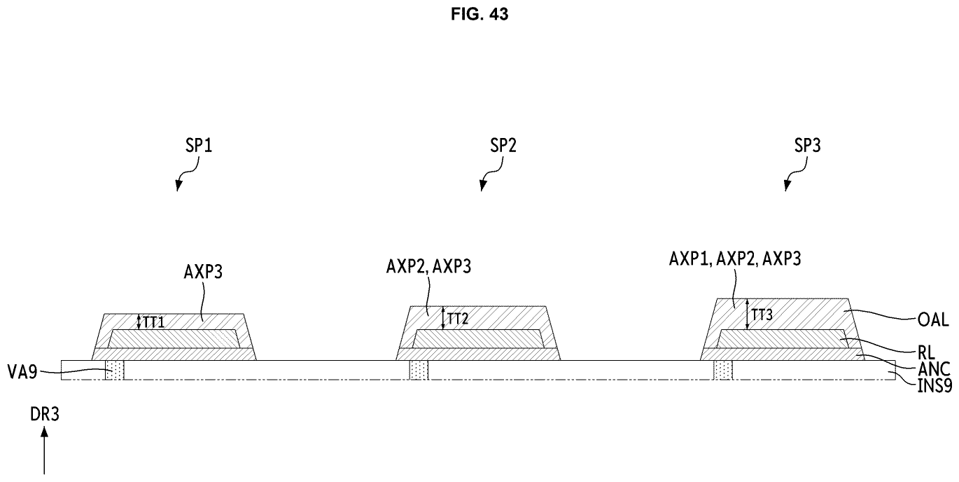

Thereafter, as illustrated in FIG. 43, by patterning the third preliminary step layer AXL3 and the connection electrode layer ANCL together by a photolithography process, the connection electrode ANC of the first sub-pixel area SP1, the connection electrode ANC of the second sub-pixel area SP2, and the connection electrode ANC of the third sub-pixel area SP3 may be formed, and the optical auxiliary layers OAL having different thicknesses may be formed on the reflective layer RL of the first sub-pixel area SP1, the reflective layer RL of the second sub-pixel area SP2, and the reflective layer RL of the third sub-pixel area SP3. For example, the optical auxiliary layer OAL of the first sub-pixel area SP1 may include a third step layer AXP3, the optical auxiliary layer OAL of the second sub-pixel area SP2 may include the second step layer AXP2 and a third step layer AXP3, and the optical auxiliary layer OAL of the third sub-pixel area SP3 may include the first step layer AXP1, the second step layer AXP2, and a third step layer AXP3. Each optical auxiliary layer OAL may be formed on an upper surface of each reflective layer RL and side surfaces of each reflective layer RL. In addition, an edge of each optical auxiliary layer OAL may be formed on an edge of an upper surface of each connection electrode ANC.

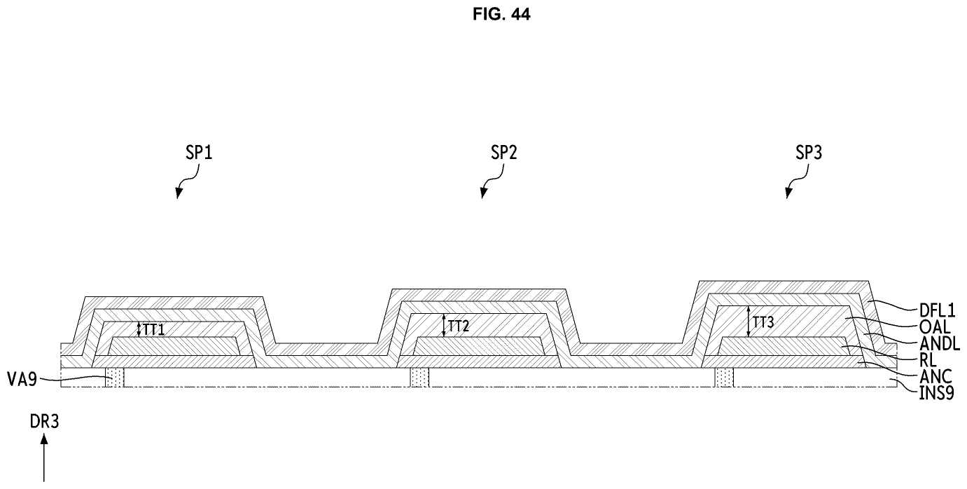

Next, as illustrated in FIG. 44, a first electrode layer ANDL may be formed on the optical auxiliary layers OAL and the ninth insulating layer INS9, and a first preliminary capping layer DFL1 may be formed on the first electrode layer ANDL. A cleaning process may be performed after each of the processes of forming the first step layer AXP1, the second step layer AXP2, and the third step layer AXP3 described above. In this case, an electrostatic chuck (ESC)-type cleaning process may be performed in order to prevent or reduce damage to the exposed preliminary reflective layer RLL and the reflective layer RL.

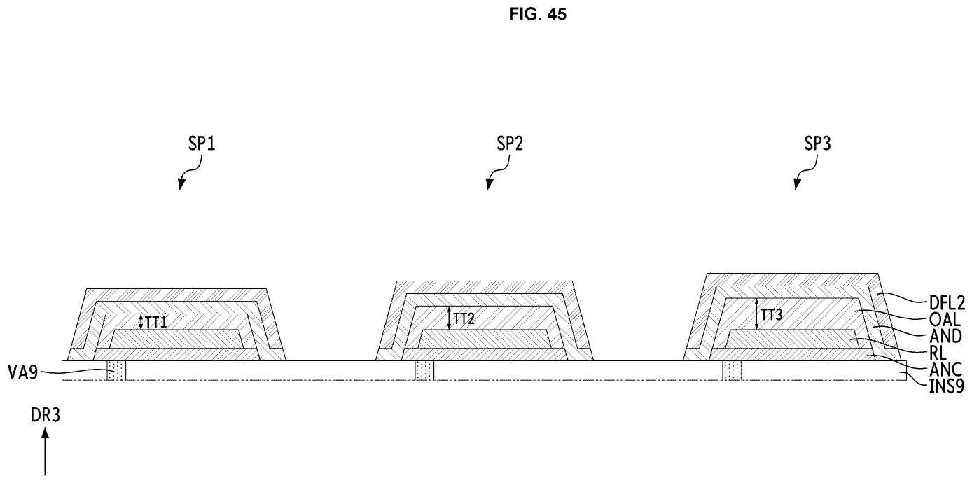

Thereafter, as illustrated in FIG. 45, by patterning the first preliminary capping layer DFL1 and the first electrode layer ANDL together through a photolithography process, the first electrode AND and a second preliminary capping layer DFL2 may be formed for each of the sub-pixel areas SP1, SP2, and SP3. Subsequently, a cleaning process may be performed. In this case, as described above, a permeation path of hydrogen fluoride may be blocked by the optical auxiliary layer OAL during the cleaning process and thus, damage to the reflective layer RL during the cleaning process may be prevented or reduce. In order to prevent or reduce the damage to the reflective layer RL, the ESC-type cleaning process described above may be utilized. However, when the cleaning process is performed on the semiconductor substrate SSUB by the ESC-type cleaning process after the first electrode AND is formed, the first electrode AND may be damaged (e.g., damaged due to corrosion) by a galvanic reaction. Accordingly, the cleaning process may be performed after the first electrode AND is performed using a stripper such as hydrogen fluoride. In this case, the above-described hydrogen fluoride may be blocked by the optical auxiliary layer OAL, and thus, the damage to the reflective layer RL may also be prevented or reduced.

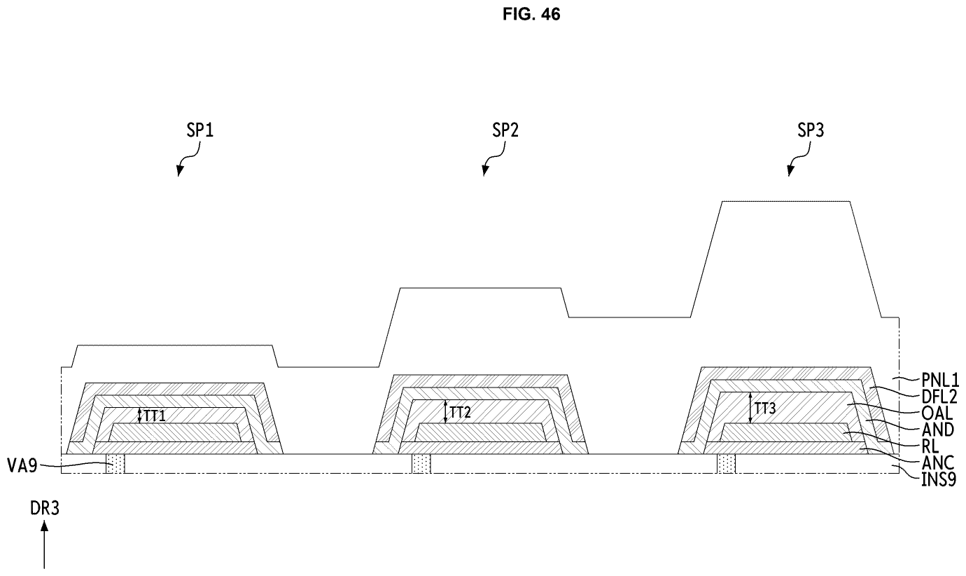

Next, as illustrated in FIG. 46, a first preliminary planarization layer PNL1 may be formed on the ninth insulating layer INS9 and the second preliminary capping layer DFL2.

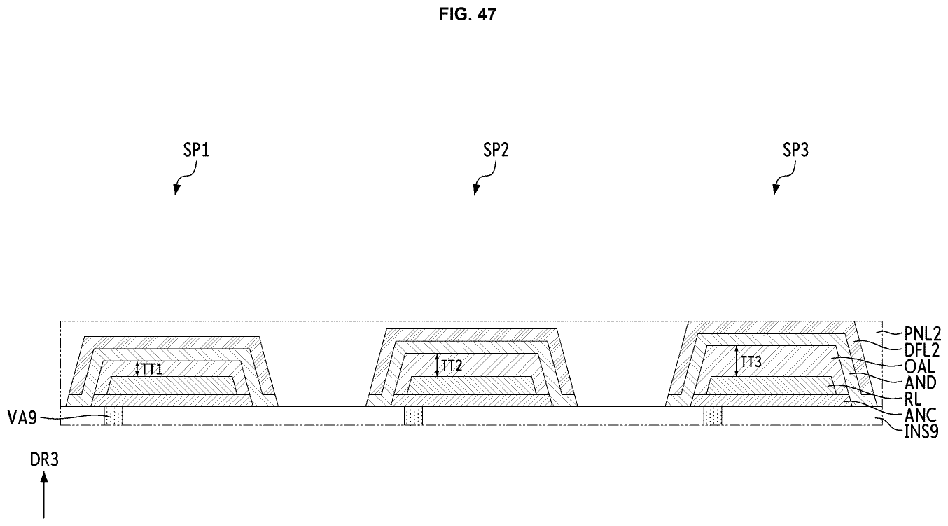

Subsequently, as illustrated in FIG. 47, by removing and planarizing the first preliminary planarization layer PNL1 through chemical mechanical polishing, a second preliminary planarization layer PNL2 may be formed. An upper surface of the second preliminary planarization layer PNL2 may be located at the same (or substantially the same) height as the highest portion of the second preliminary capping layer DFL2. For example, the upper surface of the second preliminary planarization layer PNL2 may be located at the same (or substantially the same) height as the highest portion of the second preliminary capping layer DFL2 of the third sub-pixel area SP3.

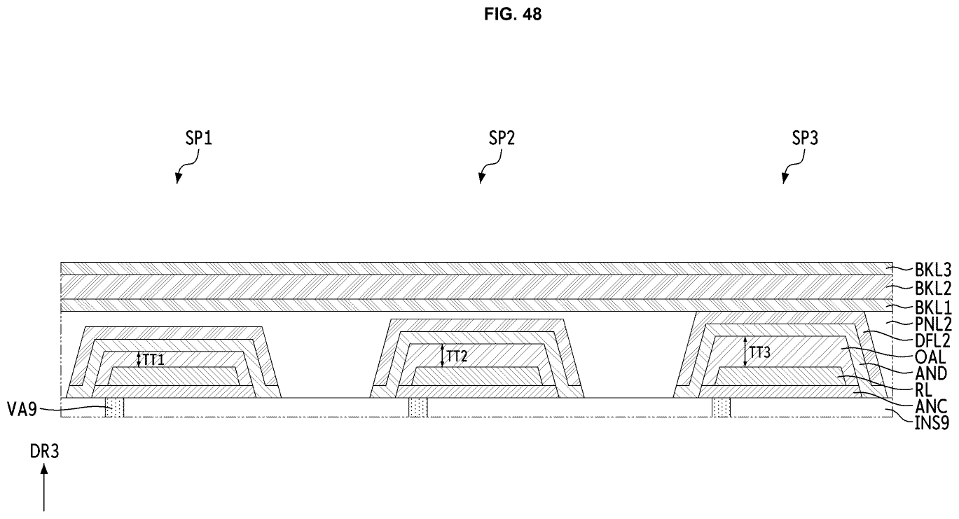

Next, as illustrated in FIG. 48, a first bank layer BKL1 may be formed on the entire surface of the semiconductor substrate SSUB including the second preliminary planarization layer PNL2 and the exposed second preliminary capping layer DFL2 (e.g., the second preliminary capping layer DFL2 of the third sub-pixel area SP3), a second bank layer BKL2 may be formed on the entire surface of the semiconductor substrate SSUB including the first bank layer BKL1, and a third bank layer BKL3 may be formed on the entire surface of the semiconductor substrate SSUB including the second bank layer BKL2.

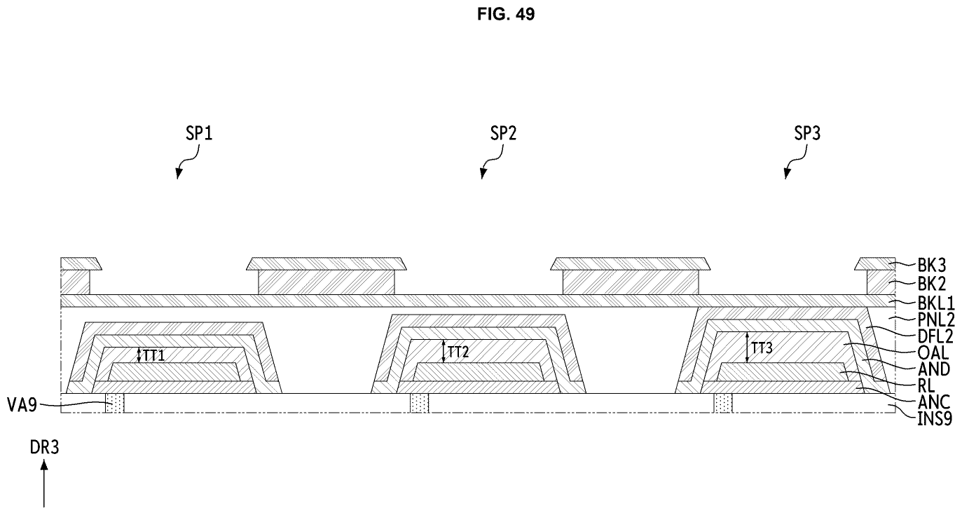

Thereafter, as illustrated in FIG. 49, by patterning the third bank layer BKL3 and the second bank layer BKL2 together through a photolithography process, the second bank BK2 and the third bank BK3 having an undercut shape may be formed.

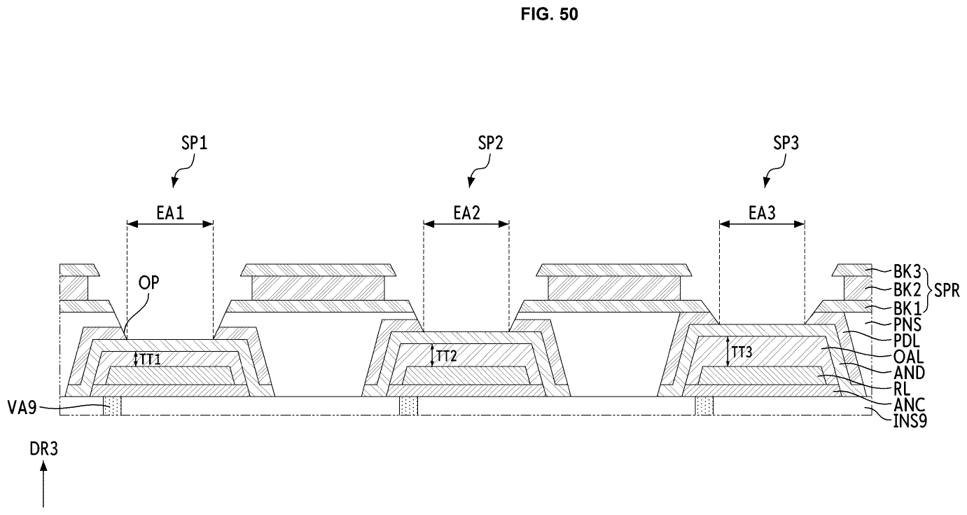

Next, as illustrated in FIG. 50, by patterning the first bank layer BKL1, the second preliminary capping layer DFL2, and the second preliminary planarization layer PNL2 together through a photolithography process, the first bank BK1 and the capping layer PDL may be formed and the first electrodes AND of the first to third sub-pixel areas SP1, SP2, and SP3 may be exposed. For example, the capping layer PDL may include openings OP defining the first emission area EA1 exposing the first electrode AND of the first sub-pixel area SP1, the second emission area EA2 exposing the first electrode AND of the second sub-pixel area SP2, and the third emission area EA3 exposing the first electrode AND of the third sub-pixel area SP3.

Next, as illustrated in FIG. 33, the light emitting stack IL may be formed on the first electrodes AND, the capping layers PDL, the planarization layer PNS, and the separators SPR, the second electrode CAT may be formed on the light emitting stack IL, and the encapsulation layer TFE may be formed on the second electrode CAT. Here, the light emitting stack IL may be separated for each of the sub-pixel areas SP1, SP2, and SP3 by the separators SPR.

Through the processes illustrated in FIGS. 37 to 45 described above, the first power connection electrode PCE1, the twelfth insulating layer INS12, and the second power connection electrode PCE2 may be formed in the power connection area PCAA. The first power connection electrode PCE1 may be made of the same material as the reflective layer RL (described above), the twelfth insulating layer INS12 may be made of the same material as the optical auxiliary layer OAL including the first step layer AXP1, the second step layer AXP2, and the third step layer AXP3 (described above), and the second power connection electrode PCE2 may be made of the same material as the first electrode AND (described above).

The display device 10 according to some embodiments may be applied to various electronic devices. An electronic device according to some embodiments may include the display device 10 (described above), and may further include modules or devices having other additional functions in addition to the display device 10.

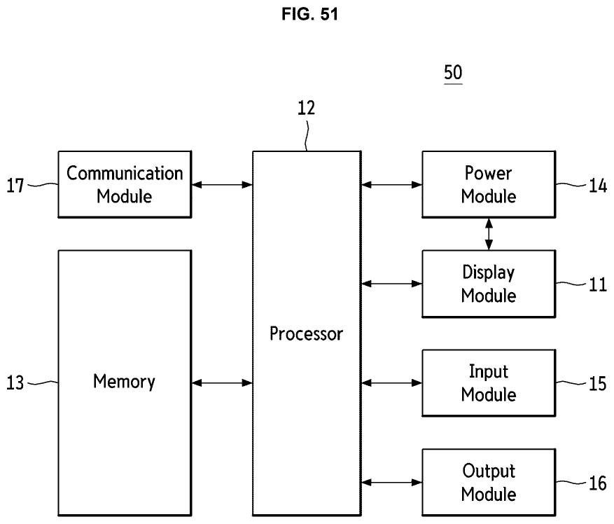

FIG. 51 is a block diagram of an electronic device 50 according to some embodiments. Referring to FIG. 51, an electronic device 50 according to some embodiments may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to a user through the display module 11. The power module 14 may include a power supply module such as a power adapter or a battery device and a power conversion module converting power supplied by the power supply module to generate power necessary for an operation of the electronic device 50. The input module 15 may provide input information to the processor 12 and/or the display module 11. The non-image output module 16 may serve to receive information other than an image received from the processor 12, such as sound information, haptic information, and light emitting information, and provide the received information to the user. The communication module 17 may be a module in charge of (e.g., controlling) transmitting and receiving information between the electronic device 50 and an external device, and may include a receiving unit and a transmitting unit.

At least one of the respective components of the above-described electronic device 50 may be included in the display device 10 according to the above-described embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 50 rather than the display device.

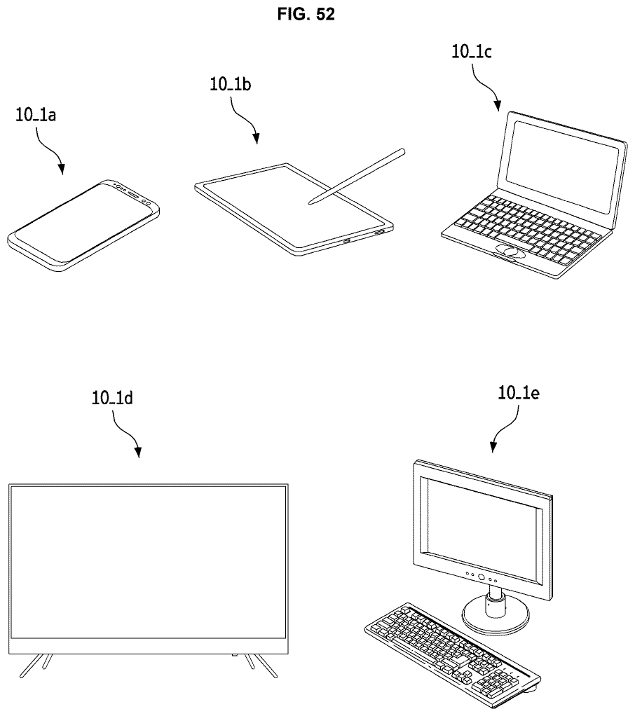

FIGS. 52 to 54 are schematic views of electronic devices according to some embodiments. FIGS. 52 to 54 illustrate examples of various electronic devices to which a display device 10 according to some embodiments may be applied.

FIG. 52 illustrates a smartphone 10_1a, a tablet personal computer (PC) 10_1b, a laptop computer 10_1c, a television (TV) 10_1d, and a monitor 10_1e for a desktop computer as examples of the electronic devices.

The smartphone 10_1a may include an input module such as a touch sensor and a communication module in addition to the display module 11 (see FIG. 51). The smartphone 10_1a may process information received through the communication module or other input modules and display the processed information through the display module of the display device.

Each of the tablet PC 10_1b, the laptop computer 10_1c, the TV 10_1d, and the monitor 10_1e for a desktop computer may include a display module and an input module, similar to the smartphone 10_1a, and may further include a communication module in some cases.

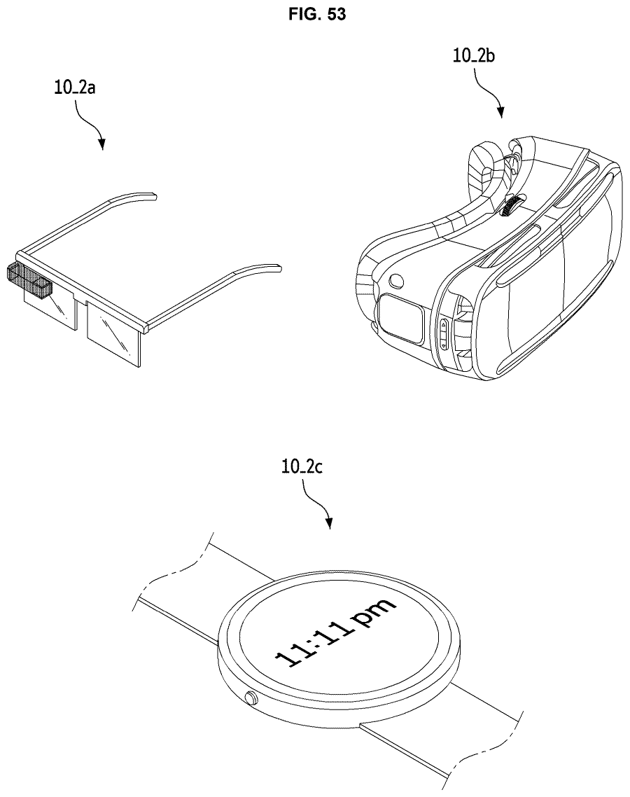

FIG. 53 illustrates an example of an electronic device that may include a display device 10, and the electronic device may be a wearable electronic device. The wearable electronic device may be a smart glasses 10_2a, a head mounted display 10_2b, a smart watch 10_2c, or the like.

The smart glasses 10_2a and the head mounted display 10_2b may include a display module emitting a display image and a reflector reflecting the emitted display image and providing the emitted display image to user's eyes, and accordingly, may provide a virtual reality screen or an augmented reality screen to the user.

The smart watch 10_2c may include a biometric sensor as an input device, and may provide biometric information recognized through the biometric sensor to the user through the display module.

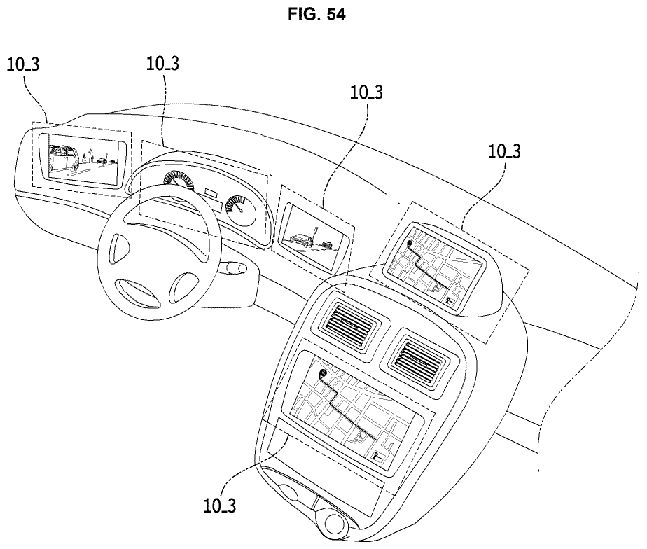

FIG. 54 illustrates an electronic device including a display device 10 that may be applied to a vehicle. For example, an electronic device 10_3 may be applied to an instrument board, a center fascia, or the like, of the vehicle or applied to a center information display (CID) located on a dashboard of the vehicle, a room mirror display substituting for a side-view mirror, or the like.

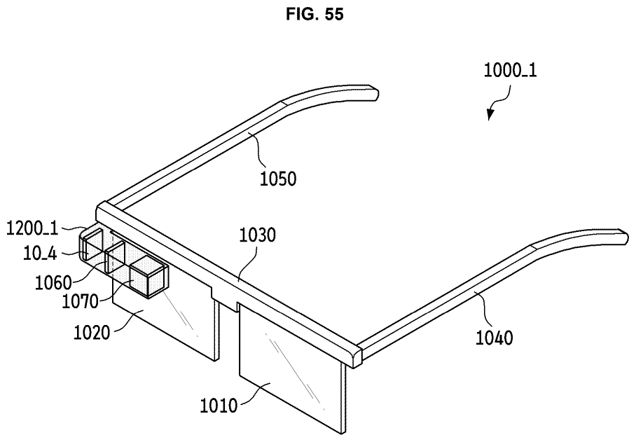

FIG. 55 is a perspective view illustrating a head mounted display device according to some embodiments. For example, FIG. 55 may be a view illustrating a detailed configuration of the smart glasses 10_2a of FIG. 53.

Referring to FIG. 55, a head mounted display device 1000_1 according to some embodiments may be a glasses-type display device in which a display device housing portion 1200_1 is implemented to have a light weight and a small size. The head mounted display device 1000_1 according to some embodiments may include a display device 10_4, a left eye lens 1010, a right eye lens 1020, a support frame 1030, glasses frame legs 1040 and 1050, an optical member 1060 (e.g., a lens), an optical path conversion member 1070 (e.g., a mirror), and a display device housing portion 1200_1.

The display device housing portion 1200_1 may include the display device 10_4, the optical member 1060, and the optical path conversion member 1070. An image displayed on the display device 10_4 may be magnified by the optical member 1060, converted in an optical path by the optical path conversion member 1070, and provided to a user's right eye through the right eye lens 1020. For this reason, a user may view an augmented reality image in which a virtual image displayed on the display device 10_4 through his/her right eye and a real image seen through the right eye lens 1020 are combined with each other.

It is illustrated in FIG. 55 that the display device housing portion 1200_1 is located at a right end of the support frame 1030, but some embodiments of the present disclosure are not limited thereto. For example, the display device housing portion 1200_1 may be located at a left end of the support frame 1030, and in this case, an image of the display device 10_4 may be provided to a user's left eye. In some embodiments, the display device housing portions 1200_1 may be located at both the left and right ends of the support frame 1030, and in this case, the user may view an image displayed on the display device 10_4 through both his/her left and right eyes.

In concluding the detailed description, those skilled in the art will appreciate that many variations and modifications can be made to some embodiments without departing from the spirit and scope of embodiments according to the present disclosure. Therefore, the disclosed embodiments of the present disclosure are used in a generic and descriptive sense only and not for purposes of limitation.

What is claimed is:

1. A display device comprising:
a substrate comprising a first sub-pixel area and a second sub-pixel area;
a connection electrode in the first sub-pixel area and the second sub-pixel area on the substrate;
a reflective layer on the connection electrodes;
an optical auxiliary layer on the connection electrodes surrounding the reflective layer;
a first electrode on the substrate and the connection electrodes surrounding the optical auxiliary layer and the connection electrodes, and contacting side surfaces of the connection electrodes;
a capping layer on the first electrodes and comprising openings overlapping the first electrodes;
a light emitting stack on the first electrodes and the capping layer; and
a second electrode on the light emitting stack.

2. The display device of claim 1, wherein an edge of the optical auxiliary layer is on an edge of an upper surface of the connection electrodes.

3. The display device of claim 1, wherein the reflective layer is surrounded by the connection electrodes and the optical auxiliary layer.

4. The display device of claim 1, wherein the optical auxiliary layer has a thickness of 100 angstrom (Å) or less.

5. The display device of claim 1, wherein the optical auxiliary layer comprises silicon oxide.

6. The display device of claim 1, further comprising a buffer layer between the reflective layer and the optical auxiliary layer.

7. The display device of claim 6, wherein the buffer layer is between the reflective layer and the optical auxiliary layer on an upper surface of the reflective layer.

8. The display device of claim 6, wherein the buffer layer has a thickness of 10 angstrom (Å) or less.

9. The display device of claim 6, wherein the buffer layer and the connection electrodes comprise a same material.

10. The display device of claim 6, wherein the buffer layer comprises titanium nitride.

11. The display device of claim 1, wherein the optical auxiliary layer in the first sub-pixel area has a first thickness and the optical auxiliary layer in the second sub-pixel area has a second thickness, the first thickness being different than the second thickness.

12. The display device of claim 6, further comprising a power connection unit connected to the second electrode,
wherein the power connection unit comprises:
a first power connection electrode connected to a power connection area;
a power buffer layer on the first power connection electrode; and
a second power connection electrode on the power buffer layer and connected to the second electrode.

13. The display device of claim 12, wherein the first power connection electrode and the reflective layer comprise a first material,
the power buffer layer and the buffer layer comprise a second material, and
the second power connection electrode and the first electrode comprise a third material.

14. An electronic device comprising:
a display device having a resolution of 4,000 pixels per inch (PPI) or more;
an optical member outside of the display device and configured to adjust a path of light emitted from the display device; and
a case surrounding the display device and the optical member,
the display device comprising:
a substrate;
a connection electrode on the substrate;
a reflective layer on the connection electrode;
an optical auxiliary layer on the connection electrode surrounding the reflective layer;
a first electrode on the substrate surrounding the optical auxiliary layer and the connection electrode, and contacting side surfaces of the connection electrode;
a capping layer on the first electrode and having an opening overlapping the first electrode;
a light emitting stack on the first electrode and the capping layer; and
a second electrode on the light emitting stack.

15. The electronic device of claim 14, wherein the optical member comprises at least one of a lens or a mirror.

16. The electronic device of claim 14, wherein the electronic device is a wearable device comprising at least one of a head mounted display, a smart glasses, or a smart watch.

17. A method for fabricating a display device, comprising:
forming an insulating layer on a substrate comprising first sub-pixel area and a second sub-pixel area, the insulating layer comprising a via electrode therein;
forming a connection electrode layer on the insulating layer, the connection electrode layer being connected to the via electrode;
forming a preliminary reflective layer on the connection electrode layer;
forming a reflective layer in the first sub-pixel area and the second sub-pixel area by patterning the preliminary reflective layer;
forming an auxiliary layer on the connection electrode layer covering the reflective layer;
forming an optical auxiliary layer and a connection electrode in the first sub-pixel area and the second sub-pixel area by patterning the auxiliary layer and the connection electrode layer;
forming a first electrode layer on the insulating layer covering the optical auxiliary layer and the connection electrode;
forming a first preliminary capping layer on the first electrode layer;
forming a second preliminary capping layer and a first electrode in the first sub-pixel area and the second sub-pixel area by patterning the first preliminary capping layer and the first electrode layer;
forming a capping layer and uncovering a portion of the first electrode by forming an opening in the second preliminary capping layer;
forming a light emitting stack on the first electrode and the capping layer; and
forming a second electrode on the light emitting stack.

18. The method for fabricating a display device of claim 17, further comprising, before patterning the preliminary reflective layer, forming a preliminary buffer layer on the preliminary reflective layer and forming a buffer layer by patterning the preliminary buffer layer.

19. The method for fabricating a display device of claim 17, further comprising, before forming the opening in the second preliminary capping layer,
forming a preliminary planarization layer on the insulating layer covering the second preliminary capping layer and the first electrode;
forming a planarization layer by polishing a surface of the preliminary planarization layer until the second preliminary capping layer in at least one of the first sub-pixel area or the second sub-pixel area is uncovered;
forming a first bank layer, a second bank layer, and a third bank layer on the second preliminary capping layer and the planarization layer;
forming a third bank and a second bank having an undercut shape and uncovering the first bank layer, by patterning the third bank layer and the second bank layer, wherein the patterning the third bank layer and the second bank layer is performed using photolithography and having a first etch rate for the third bank layer and a second etch rate for the second bank layer that is lower than the first etch rate; and
forming a first bank uncovering the second preliminary capping layer by patterning the first bank layer.

20. The method for fabricating a display device of claim 17, further comprising, before patterning the preliminary reflective layer, forming a preliminary step layer on the preliminary reflective layer and forming a step layer in at least one of the first sub-pixel area or the second sub-pixel area by patterning the preliminary step layer, wherein the preliminary step layer is deposited by an atomic deposition method.
